(19) United States
(12) Patent Application Publication
(10) Pub. No.: US 2006/0234396 A1
(43) Pub. Date: Oct. 19, 2006

(54) Method for producing structure

(75) Inventors: Tadabumi Tomita, Shizuoka (JP); Yoshinori Hotta, Aichi (JP); Akio Uesugi, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/405,401

(22) Filed: Apr. 18, 2006

(30) Foreign Application Priority Data
Apr. 18, 2005 (JP) 2005-119418
Jul. 29, 2005 (JP) 2005-221625

(51) Int. Cl. H01L 21/00; H01L 21/76

(52) U.S. Cl. 438/3; 438/401

(57) ABSTRACT

Disclosed is a method for producing a structure having: a stripping step in which an aluminum member including an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to produce a structure composed of the anodized layer with a plurality of recesses. The method can produce a structure having regularly arranged recesses in a reduced time.

The entire contents of the documents cited in this specification are herein incorporated by reference.

### BACKGROUND OF THE INVENTION

This invention relates to a microstructure and its production method, and more specifically, to a method for producing a nanostructure using an aluminum member having on a surface thereof an anodized layer containing a plurality of micropores.

In the technical field of metal and semiconductor thin films, wires, dots, and the like, an electrically, optically, or chemically unique phenomenon is known to occur due to confinement of motions of free electrons in the metals or semiconductors within a size smaller than a certain characteristic length. Such phenomenon is called “quantum mechanical size effect” or simply “quantum size effect.” Functional materials employing such unique phenomenon are under active research and development. More specifically, materials having a structure smaller than several hundred nanometers in size are called “microstructures” or “nanostructures”, and these materials are the subject of one of the current efforts in material development.

Exemplary methods for manufacturing such microstructures include processes in which a nanostructure is directly manufactured by a semiconductor processing technique such as photolithography, electron beam exposure, X-ray exposure, or other fine patterning formation technique.

Of particular note is the considerable amount of research being conducted today on the process for producing nanostructures having an ordered microstructure.

One method of forming an ordered structure in a self-ordered manner involves subjecting aluminum to anodizing treatment in an electrolyte, to thereby obtain an anodized alumina film (anodized film). The anodized film is known to have ordered fine pores (micropores) each having a diameter of about several nanometers to about several hundred nanometers. It is also known that, when a perfectly ordered arrangement is realized by the self-ordering of this anodized layer, hexagonal columnar cells are theoretically formed, each cell having a base in the shape of a regular hexagon centered on a micropore, and that the lines connecting neighboring micropores will form equilateral triangles.

For example, Masuda, H. et al., Jpn. J. Appl. Phys., Vol. 37 (1998), pp. L1340-1342, Part 2, No. 11A, 1 Nov. 1998 (FIG. 2) describes an anodized layer having micropores with a variation in the pore diameter of within 3%. Another related publication [“Hyomen Gijutsu Binran (Handbook of Surface Technology)”, edited by The Surface Finishing Society of Japan (The Nikkan Kogyo Shimbun, Ltd., 1998), pp. 490-553] describes natural formation of fine pores in an anodized film in the course of oxidation. Further, Masuda, H., “Highly ordered metal nanohole arrays based on anodized alumina”, Solid State Physics, 1996, Vol. 31, No. 5, pp. 493-499 proposes formation of an Au dot array on an Si substrate using a porous oxide film as a mask.

In an anodized layer, a plurality of micropores take on a honeycomb structure in which the pores are formed parallel in a direction substantially vertical to the substrate surface, and at substantially equal intervals. This point is deemed to be the most distinctive characteristic of the anodized layer in terms of material. Another remarkable feature of the anodized layer, thought to be absent in other materials, is that the layer can relatively freely be controlled in pore diameter, pore spacing and pore depth (see Masuda, 1996).

Known examples of applications of anodized layers include various types of devices, such as nanodevices, magnetic devices, and light-emitting devices. For example, JP 2000-31462 A mentions a number of applications, including magnetic devices in which the micropores are filled with the magnetic metal cobalt or nickel, devices in which the micropores are filled with the luminescent material ZnO, and biosensors in which the micropores are filled with an enzyme/antibody.

In addition, in the field of biosensing, JP 2003-268592 A describes an example in which a structure obtained by filling the interior of micropores in an anodized layer with a metal is used as a sample holder for Raman spectroscopy.

Raman scattering refers to the scattering of incident light (photon) caused by inelastic collision of the incident light with a particle, which collision induces change in energy. Raman scattering is used as a technique for spectroscopic analysis, but the scattered light for measurement must have an enhanced intensity for improvement of sensitivity and accuracy of analysis.

A surface-enhanced resonance Raman scattering (SERRS) phenomenon is known as a phenomenon for enhancing Raman scattered light. The phenomenon is such that scattering of light by molecules of certain species adsorbed on a surface of a metal electrode, a sol, a crystal, a deposited film, a semiconductor, or the like is enhanced as compared to scattering in a solution. A significant enhancing effect of 10¹¹ to 10¹⁴ times may be observed, in particular, on gold or silver. The mechanism causing the SERRS phenomenon is not yet clarified, but surface plasmon resonance presumably has an effect thereon. JP 2003-268592 A also aims at utilizing the principle of plasmon resonance as a means for enhancing the Raman scattering intensity.

Plasmon resonance refers to a phenomenon in which a plasmon wave as an electron density wave localized on the surface of a noble metal such as gold or silver interacts with an electromagnetic wave when the surface is irradiated with light and brought into an excited state (resonance excitation), leading to a resonant state formation. Particularly, surface plasmon resonance (SPR) refers to a phenomenon in which collective vibrations of free electrons on a metal surface occur when the metal surface is irradiated with light and the free electrons are brought into excited states, which leads to a generation of surface plasmon waves bringing about a high electric field.

An electric field is enhanced by several orders (10⁸ to 10¹⁰ times, for example) in a region in the vicinity of a surface where plasmon resonance takes place, more specifically, in a region within about 200 nm from the surface, and significant enhancement in various optical effects are observed. For example, when light enters a prism having a thin film of gold or the like deposited at an angle equal to or larger than the critical angle, a change in dielectric constant of a surface of the thin film can be detected with high sensitivity as a change in intensity of reflected light due to the surface plasmon resonance phenomenon.

To be specific, use of an SPR apparatus applying the surface plasmon resonance phenomenon allows measurement or kinetic analysis of a reaction amount or bonding amount between biomolecules without labeling and in real time. The SPR apparatus is applied to researches on immune response, signal transduction, or interaction between various substances such as proteins and nucleic acids. Recently, a paper describing analysis of trace amounts of dioxins using an SPR apparatus has also been published (see I. Karube et al., Analytica Chimica Acta, 2001, Vol. 434, No. 2, pp. 223-230).

Various methods for enhancing plasmon resonance have been studied, and a technique of localizing plasmon by forming a metal into isolated particles, not into a thin film is known. For example, JP 2003-268592 A describes a technique of localizing plasmon by providing metal particles in pores of an ordered anodized film.

A research report describes that when localized plasmon resonance caused by metal particles is utilized, the metal particles locating close to one another enhance the electric field intensity at a gap between the metal particles, thereby realizing a state where plasmon resonance occurs more easily (see Takayuki Okamoto, “Researches on interaction of metal nanoparticles and on biosensors”, on-line, URL: http://www.plasmon.jp/reports/okamoto.pdf, searched on Nov. 27, 2003).

Production of an anodized layer having regularly arranged micropores by using self-ordering of the anodized layer has generally been accomplished with a self-ordering step in which electrolysis is conducted for a long time under particular electrolytic conditions to promote regular formation of the micropores, and a layer removal step using a mixed aqueous solution of chromic acid and phosphoric acid in which the anodized layer obtained in the self-ordering step is so dissolved as to expose the bottom part of the most regularly arranged micropores on the surface.

JP 61-88495 A describes subjecting a member of aluminum or its alloy to an anodizing treatment to form a porous layer, and using reverse-electrolytic means to strip the porous layer off the substrate and obtain the porous layer.

In the meanwhile, production of a fine structure having a high aspect ratio by fine patterning such as X ray exposure can be accomplished if a technique involving use of X-ray lithography such as LIGA process is used. The apparatus used in such production, however, is expensive because it requires use of a high quality X ray source (with high wave uniformity and beam straightness) only realized by a large scale accelerator installation such as Spring-8, and, in fact, the production cannot be carried out industrially unless the resulting product has an application which adds a high value to the product.

In contrast, self-ordering anodization is capable of processing a relatively large area at a reduced cost, and therefore, should have a wide variety of practical applications.

As described in Masuda, Hideki et al., Appl. Phys. Lett., 71(19), 10 Nov. 1997 and Masuda, H. et al., J. Electrochem. Soc., Vol. 144, No. 5, May 1997, pp. L127 to L130, an aluminum material having an aluminum purity of 99.99% is generally used in the production of a nanostructure by forming an anodized layer on an aluminum substrate, with the micropores of the anodized layer being regularly arranged. The polishing is generally conducted by electrolytic polishing.

When the nanostructure produced by such self-ordering anodization is used in an article requiring a particularly high surface smoothness such as optical device and magnetic device, S/N ratio has been known to be insufficient due to decrease in the signal intensity.

In view of such situation, use of an aluminum substrate having flat mirror finished surface is highly desirable. Such mirror finished high purity aluminum, however, is not commercially available, and various methods including the most popular electrolytic polishing are used to polish the aluminum surface to mirror finished grade.

However, defects of visually recognizable level such as “blisters” or “rolling streaks” could not be removed by the electrolytic polishing, and accordingly, use of the resulting nanostructure in the application involving an electromagnetic processing such as an optical device or magnetic device was difficult.

The aluminum substrate is produced by repeated melting for purification in a melting furnace, and in the melting furnace, the molten metal is agitated by using a gas such as air or inert gas. As a consequence, the gas is trapped in the metal, and the metal has to be degassed under reduced pressure. In the case of high purity material having an aluminum purity in excess of 99.99%, the metal needs severe agitation for floating of trace amounts of impurities to the surface, and this results in a higher content of bubbles in the resulting metal, and hence, in insufficient degassing.

When such aluminum including bubbles is rolled, raised parts called “blisters” with a diameter of about 50 μm to 2 mm and a depth of about 0.1 to 20 μm are generated on a rolled product. Density of the blisters is generally in the range of several blisters to several hundred blisters per square decimeter.

The aluminum substrate is produced in the form of a sheet by rolling. Rolling is a method in which a slab (ingot) is passed between two parallel rolls to reduce the thickness to a particular level, and this process destroys the cast structure of the slab to realize a uniform structure. Rolling is divided into hot rolling in which the slab is heated before the rolling, and cold rolling in which the slab is rolled at room temperature.

Rolling is usually accomplished by the hot rolling in which thickness of the slab is reduced and the cast structure of the slab is changed into rolled structure of the sheet, and the subsequent cold rolling in which the sheet is finished.

As described above, the aluminum substrate is extended by the rolling process. The process occasionally produces an unevenness called “rolling streak” which extends in the direction of the rolling. This rolling streak is a surface irregularity of a size visually recognizable with naked eye, and is associated with unnecessarily increased Rₐ in the direction perpendicular to the rolling direction.

The relatively large surface irregularities like “blisters” or “rolling streaks” could not be removed by the electrolytic polishing, and when an aluminum substrate with such surface irregularities is used in an article requiring a particularly high surface smoothness like optical device, S/N ratio was insufficient due to decrease in the signal intensity and the like. Accordingly, there is a strong demand for a polishing capable of removing the surface irregularities.

### SUMMARY OF THE INVENTION

However, the layer removal step using the mixed aqueous solution of chromic acid and phosphoric acid as described above generally required a long time of several hours to well over ten hours although the time required may vary with the thickness of the anodized layer. In addition, the anodized layer could not be effectively used because of the dissolution.

The anodized layer produced under anodizing conditions described in JP 61-88495 A had an excessively large coefficient of variation in the pore diameter, and could not be used as a sample stage for Raman spectroscopic analysis, or the like. When the thickness of the layer is reduced by the current recovery method described in JP 61-88495 A, the regularly arranged recesses on the surface of the aluminum member were lost and the coefficient of variation in the pore diameter was too large, and the aluminum member could not be used as a sample stage for Raman spectroscopic analysis, or the like.

In view of the situation as described above, an object of the present invention is to provide a method capable of producing a structure having regularly arranged recesses in a reduced time, as well as the structure producible by such a method.

Another object of the present invention is to provide a method capable of producing a nanostructure having micropores (fine pores) made by anodization or anodic formation, which is free from visually recognizable defects such as rolling streaks and blisters and which can be used in electromagnetic device.

Yet another object of the present invention is to provide novel nanostructures and nanodevices, which can be used in a wide variety of applications, by using as a base the nanostructure having micropores that is producible by such a production method as above.

The inventors of the present invention made an intensive research to produce a structure having regularly arranged recesses in a reduced time, and found that a structure composed of an anodized layer having regularly arranged recesses can be produced by electrolyzing an aluminum member having an anodized layer having regularly arranged micropores in an aqueous solution of an acid by using the aluminum member for a cathode to thereby strip the anodized layer. Aspect (I) of the present invention has been achieved on the basis of such finding.

Accordingly aspect (I) of the present invention provides the following (1) to (9).

(1) A Method for producing a structure comprising:

a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to produce a structure composed of the anodized layer with a plurality of recesses.

(2) A method for producing a structure comprising:

a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to obtain the aluminum substrate with a plurality of recesses; and

an anodizing step in which the aluminum substrate with a plurality of recesses is anodized to produce a structure composed of the aluminum substrate with a plurality of recesses that is provided on its surface with an anodized layer containing micropores.

(3) The method for producing a structure according to the above (1) wherein the micropores in the structure composed of the anodized layer with a plurality of recesses produced by the stripping step have an average pore diameter of 8 to 200 nm and an average pore interval of 23 to 600 nm.

(4) The method for producing a structure according to the above (2) wherein the micropores in the structure produced by the anodizing step have an average pore diameter of 8 to 200 nm and an average pore interval of 23 to 600 nm.

(5) The method for producing a structure according to any one of the above (1) to (4) wherein the aluminum substrate constituting the aluminum member is the one producible by performing polishing on an aluminum substrate having an aluminum purity of at least 99.9% at least by mechanical polishing to an arithmetical mean roughness Rₐ of up to 0.1 μm and a glossiness of at least 60%.

(6) The method for producing a structure according to the above (5) wherein the mechanical polishing is electrolytic-abrasive polishing.

(7) A structure obtainable by the method for producing a structure according to any one of the above (1) to (6).

(8) An electromagnetic device comprising the structure obtainable by the method for producing a structure according to the above (1) wherein the plurality of recesses in the structure have in their interior a metal material or a magnetic material.

(9) An electromagnetic device comprising the structure obtainable by the method for producing a structure according to the above (2) wherein the micropores in the structure have in their interior a metal material or a magnetic material.

Aspect (II) of the present invention provides the following (10) to (27).

(10) A method for producing a nanostructure comprising the steps of performing polishing on an aluminum substrate having an aluminum purity of at least 99.9% at least by mechanical polishing to an arithmetical mean roughness Rₐ of up to 0.1 μm and a glossiness of at least 60%, and further performing anodizing on the aluminum substrate to thereby produce a nanostructure provided in its surface with micropores.

(11) The method for producing a nanostructure according to the above (10) wherein the arithmetical mean roughness Rₐ of up to 0.1 μm is the roughness measured by a sapphire probe having a tip radius of 10 μm.

(12) The method for producing a nanostructure according to the above (10) wherein the mechanical polishing is electrolytic-abrasive polishing.

(13) The method for producing a nanostructure according to the above (10) wherein the polishing is accomplished by conducting the mechanical polishing and then an auxiliary chemical polishing or electrolytic polishing.

(14) The method for producing a nanostructure according to the above (10) wherein the polishing is accomplished by conducting the mechanical polishing and then an auxiliary chemical polishing and/or electrolytic polishing, and then additionally using a chemical mechanical polishing (CMP) method or barrier layer removing method.

(15) The method for producing a nanostructure according to the above (10) wherein the polishing is accomplished by conducting an electrolytic-abrasive polishing, and then additionally using a CMP method or barrier layer removing method.

(16) The method for producing a nanostructure according to any one of the above (10) to (15) wherein the micropores have an average pore diameter of 20 to 30 nm and an average pore interval of 60 to 65 nm.

(17) The method for producing a nanostructure according to any one of the above (10) to (15) wherein the anodizing is accomplished by conducting an electrolysis at a constant voltage of 22 to 27 V.

(18) The method for producing a nanostructure according to any one of the above (10) to (15) wherein the micropores have an average pore diameter of 30 to 35 nm and an average pore interval of 95 to 105 nm.

(19) The method for producing a nanostructure according to any one of the above (10) to (15) wherein the anodizing is accomplished by conducting an electrolysis at a constant voltage of 38 to 42 V.

(20) The method for producing a nanostructure according to any one of the above (10) to (15) wherein the micropores have an average pore diameter of 8 to 200 nm and an average pore interval of 23 to 600 nm and preferably 24 to 500 nm.

(21) A method for producing a nanostructure by using the nanostructure obtainable by the method for producing a nanostructure according to any one of the above (10) to (20) as a mold.

(22) A nanostructure producible by pressing the mold of the above (21).

(23) An electron releasing device comprising the nanostructure obtainable by the method for producing a nanostructure according to any one of the above (10) to (21) wherein the micropores having a regular nanostructure in the nanostructure have in their interior an electron releaser.

(24) A photonic device capable of controlling optical dispersion properties and/or optical propagation properties and comprising the nanostructure obtainable by the method for producing a nanostructure according to any one of the above (10) to (21) wherein the micropores having a regular nanostructure in the nanostructure have in their interior a substance having a dielectric constant different from the substrate.

(25) A electromagnetic device comprising the nanostructure obtainable by the method for producing a nanostructure according to any one of the above (10) to (21) wherein the micropores having a regular nanostructure in the nanostructure have in their interior a metal material or magnetic material.

(26) A light-emitting device comprising the nanostructure obtainable by the method for producing a nanostructure according to any one of the above (10) to (21) wherein the micropores having a regular nanostructure in the nanostructure have in their interior a light-emitting substance.

(27) A nanostructure provided in its surface with micropores which is obtainable by performing anodizing on an aluminum substrate having an aluminum purity of at least 99.9%, an arithmetical mean roughness Rₐ of up to 0.1 μm as calculated from roughness values found in an area of not less than 1 mm² in a rolling direction and a direction perpendicular thereto, and a glossiness of at least 60%.

The structure production method according to aspect (I) of the present invention is capable of producing a structure having regularly arranged recesses in a reduced time.

The nanostructure production method according to aspect (II) of the present invention is capable of producing a nanostructure comprising an anodized layer, in which a low surface roughness and a high glossiness are attained, and accordingly, an improved S/N ratio is realized when the structure is used for an optical device or a magnetic device.

The nanostructure production method according to aspect (II) of the present invention is a method for producing a nanostructure having micropores made by anodization or anodic formation, wherein the anodization is conducted after mirror finishing the surface of a high purity aluminum plate by removing visually recognizable defects generated on the surface, such as “blisters” and rolling streaks, to thereby improve smoothness of the surface of the anodized nanostructure. In consequence, a structure which is ordered over a large area and applicable to an electromagnetic device such as optical device or magnetic device can be obtained in a simple procedure.

### BRIEF DESCRIPTION OF THE DRAWING

In the accompanying drawing:

FIGS. 1A through 1D are diagrams illustrating the structure production method according to aspect (I) of the present invention.

### DETAILED DESCRIPTION OF THE INVENTION

(Aspect (I)]

Next, aspect (I) of the present invention is described in detail.

A first mode in aspect (I) of the present invention is directed to a method for producing a structure comprising: a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid-solution by using the aluminum member for a cathode to thereby strip the anodized layer off the aluminum substrate so as to produce a structure composed of the anodized layer with a plurality of recesses.

<Aluminum Member>

The aluminum member used in the present invention includes an aluminum substrate and an anodized layer present on the surface of the aluminum substrate. This aluminum member can be obtained by anodizing the surface of the aluminum substrate.

<Aluminum Substrate>

The aluminum substrate is not particularly limited, and examples of such aluminum substrate include commercially available aluminum substrates; a substrate prepared through vapor deposition of high purity aluminum on low purity aluminum (for example, recycled material); a substrate made of a silicon wafer, quartz, glass or the like whose surface is coated with a high purity aluminum by a method such as vapor deposition or sputtering; and an aluminum-laminated resin substrate.

Of the aluminum substrate, the surface to be provided with the anodized layer through anodizing treatment has an aluminum purity of preferably 99.5 wt % or more, more preferably 99.80 wt % or more, and still more preferably 99.9 wt % or more; but preferably less than 99.99 wt %, and more preferably 99.95 wt % or less. An aluminum purity of 99.5 wt % or more allows a sufficiently ordered pore arrangement, and an aluminum purity of less than 99.99 wt % allows production at low cost.

The aluminum substrate surface is preferably subjected to a degreasing treatment and a mirror finishing treatment prior to the anodizing treatment.

<Degreasing Treatment>

Degreasing treatment is carried out for removal of an organic component (mainly oil component) or the like adhered to the surface by dissolution using an acid, an alkali, an organic solvent, or the like.

More specifically, commercially available degreasers can be used in the degreasing treatment by the prescribed method.

Alternatively, the degreasing treatment may be accomplished by immersing the aluminum substrate in a solution such as an aqueous solution of sodium hydroxide at a pH of 10 to 13 at about 30 to 50° C., or an aqueous solution of sulfuric acid at a pH of 1 to 4 at about 40 to 70° C. until the aluminum surface slightly generates air bubbles.

In a preferred degreasing procedure, an aluminum substrate is washed with acetone, and then immersed in sulfuric acid at pH 4 at 50° C. This method is preferable because the oil component on the aluminum surface is removed with little dissolution of aluminum.

<Mirror Finishing Treatment>

Mirror finishing treatment is carried out to eliminate surface irregularities from the aluminum substrate and improve the uniformity and reproducibility of sealing treatment by a process such as electrodeposition.

In the invention, the mirror finishing treatment is not subject to any particular limitation, and any suitable method known in the art can be used. Examples of suitable methods include polishing which is accomplished with various commercial polishing cloths or by the combined use of various commercial abrasives (e.g., diamond, alumina) with buffs (mechanical polishing); electrolytic polishing; and chemical polishing; which may be used either alone or in combination.

Examples of the electrolytic polishing and the chemical polishing include various methods described in the 6^{th} edition of “Aluminum Handbook” (Japan Aluminum Association, 2001, pp. 164-165).

A preferable example of the mirror finishing treatment is a method in which polishing is performed using abrasives while varying over time the abrasive used from coarser particles to finer particles, followed by electrolytic polishing (electrolytic-abrasive polishing method). In such a case, the final abrasive used is preferably a #1500-grit abrasive. When this method is used, rolling streaks generated during the production of the aluminum substrate by rolling can be removed. The aluminum substrate is preferably subjected to finish polishing by CMP or barrier layer removal method as will be described with regard to aspect II of the present invention.

Mirror finishing treatment is preferably carried out to realize a surface having an arithmetical mean roughness Rₐ (hereinafter also referred to as “mean surface roughness Rₐ”) of 0.1 μm or less and a glossiness of at least 60% (for example, a mean surface roughness Rₐ of 0.03 μm or less and a glossiness of at least 70%) . The mean surface roughness Rₐ is preferably 0.02 μm or less. The glossiness is preferably at least 80%.

The glossiness is the specular reflectance which can be determined in accordance with JIS Z 8741-1997 (Method 3: 60 degree specular glossiness) in a direction perpendicular to the rolling direction.

<Anodizing Treatment>

The anodizing treatment can be accomplished by any conventional method known in the art. More specifically, the anodizing treatment is preferably carried out by the self-ordering method as described below.

The self-ordering method is a method which improves the ordering property of an anodized layer by using the regularly-arranged nature of the micropores in the anodized layer and eliminating factors that disturb a regular arrangement. Specifically, an anodized layer is formed on high-purity aluminum at a voltage appropriate for the type of electrolyte solution used and at a low speed over an extended period of time (of several hours to well over ten hours, for example).

Typical examples of self-ordering methods include those described in Masuda, H. et al., J. Electrochem. Soc., Vol. 144, No. 5, p. L128 (May 1997); Masuda, H. et al., Jpn. J. Appl. Phys., Vol. 35, Part 2, No. 1B, p. L126 (1996); Masuda, H. et al., Appl. Phys. Lett., Vol. 71, No. 19, p. 2771 (Nov. 10, 1997); and Masuda, H. et al., Jpn. J. Appl. Phys., Vol. 37 (1998), pp. L1340-1342, Part 2, No. 11A, 1 Nov. 1998 (FIG. 2).

The methods described in these documents share technical characteristics that each method involves use of a high purity material, use of a specific voltage adequate for the electrolyte solution used, and use of a relatively low temperature for a long period of time. To be specific, each method involves use of a material having an aluminum purity of 99.99 wt % or more, and the self-ordering method is conducted under the following conditions.

0.3 mol/L sulfuric acid, 0° C., 27 V, 450 minutes (Masuda, H. et al., J. Electrochem. Soc., Vol. 144, No. 5, p. L128 (May 1997))

0.3 mol/L sulfuric acid, 10° C., 25 V, 750 minutes (Masuda, H. et al., J. Electrochem. Soc., Vol. 144, No. 5, p. L128 (May 1997))

0.3 mol/L oxalic acid, 17° C., 40 to 60 V, 600 minutes (Masuda, H. et al., Jpn. J. Appl. Phys., Vol. 35, Part 2, No. 1B, p. L126 (1996))

0.04 mol/L oxalic acid, 3° C., 80 V, layer thickness of 3 μm (Masuda, H. et al., Appl. Phys. Lett., Vol. 71, No. 19, p. 2771 (Nov. 10, 1997))

0.3 mol/L phosphoric acid, 0° C., 195 V, 960 minutes (Masuda, H. et al., Appl. Phys. Lett., Vol. 71, No. 19, p. 2771 (Nov. 10, 1997))

The self-ordering anodizing treatment used in the present invention may employ a method involving applying electric power to an aluminum substrate as an anode in a solution having an acid concentration of 1 to 10 wt %. Examples of the solution used for the anodizing treatment include oxalic acid, sulfuric acid, citric acid, malonic acid, tartaric acid, and phosphoric acid, which may be used alone, or as a mixture of two or more such solutions.

The conditions for the self-ordering anodizing treatment cannot be determined unconditionally because the conditions vary in accordance with the electrolyte solution used. However, appropriate conditions generally include a concentration of the electrolyte solution of 0.01 to 10 mol/L, a solution temperature of 0 to 20° C., a current density of 0.1 to 10 A/dm², a voltage of 15 to 240 V, a quantity of electricity of 3 to 10000 C/dm², and an electrolysis time of 30 to 1000 minutes.

The electrolysis is preferably conducted at a constant voltage.

The anodized layer may have the characters as described below.

The thickness of the anodized layer including the barrier layer is preferably 0.1 μm or more, and more preferably 1 μm or more. The thickness within such range allows an improved ordering of the micropores.

In addition, the thickness of the anodized layer including the barrier layer is preferably 100 μm or less. The thickness within such range allows easier stripping of the anodized layer off the aluminum substrate as will be described later.

The barrier layer has a thickness of preferably 600 nm or less, more preferably 5 to 400 nm, and still more preferably 10 to 80 nm. The thickness within such range allows easier stripping in the stripping step as described later.

The average pore diameter is in the range of 8 to 500 nm, preferably 15 to 100 nm, and more preferably 20 to 80 nm. When the average pore diameter is within such range, and the micropores are to be filled with a metal, the metal is filled into the micropores more uniformly.

The coefficient of variation in pore diameter is less than 30%, and preferably 5 to 20%. The coefficient of variation in pore diameter within such range allows an increased effectiveness when the anodized layer is used in a plasmon resonance device or the like.

The coefficient of variation (CV) in pore diameter is an index of variation in pore diameter, which is defined by the following equation.
(Coefficient of variation in pore diameter)=(Standard deviation of pore diameter)/(Average pore diameter)

The micropores are preferably provided at an average pore interval in the range of 20 to 700 nm, more preferably 23 to 600 nm, and most preferably 25 to 150 nm.

The coefficient of variation in micropore interval is preferably less than 30%, and more preferably less than 20% but not less than 5%. The coefficient of variation within such range allows an increased effectiveness when the anodized layer is used in a plasmon resonance device or the like.

The micropores preferably account for an area ratio of 10 to 70%.

<Pore Widening Treatment>

The pore widening treatment refers to a treatment conducted after the anodizing treatment for enlarging the pore diameter of micropores by immersing an aluminum substrate in an aqueous acid solution or an aqueous alkali solution and dissolving the anodized layer. Such treatment facilitates control of the regularity of the micropore arrangement.

When the pore widening treatment is to be carried out with an aqueous acid solution, the aqueous solution used is preferably an aqueous solution of an inorganic acid such as sulfuric acid, phosphoric acid, nitric acid or hydrochloric acid, or a mixture thereof. The aqueous acid solution preferably has a concentration of 1 to 10 wt % and a temperature of 25 to 40° C.

When the pore widening treatment is to be carried out with an aqueous alkali solution, the aqueous alkali solution used is preferably an aqueous solution of at least one alkali selected from the group consisting of sodium hydroxide, potassium hydroxide, and lithium hydroxide. The aqueous alkali solution preferably has a concentration of 0.1 to 5 wt % and a temperature of 20 to 35° C.

Specific examples of preferred solutions include a 40° C. aqueous solution containing 50 g/L of phosphoric acid, a 30° C. aqueous solution containing 0.5 g/L of sodium hydroxide, and a 30° C. aqueous solution containing 0.5 g/L of potassium hydroxide.

The immersion time in the aqueous acid solution or aqueous alkali solution is preferably 8 to 60 minutes, more preferably 10 to 50 minutes, and even more preferably 15 to 30 minutes.

<Thickness Reducing Treatment of the Barrier Layer>

In a preferred embodiment of the present invention, the aluminum member as described above is the one wherein the barrier layer of the anodized layer has a reduced thickness. When the barrier layer has a reduced thickness, the anodized layer will be easily stripped off the aluminum substrate in the stripping step as will be described later.

The inventors of the present invention have found that thickness of the barrier layer in the anodized layer can be reduced with no adverse effect on the regularity of the micropore arrangement in the anodized layer if the voltage is reduced after the anodizing treatment gradually with no drastic change in the voltage, namely, if the voltage is reduced while maintaining the flow of the electric current with no electric current recovery period. The reason for this is believed to be that absence of the electric current recovery period contributes to the absence of fine branching.

More specifically, when a voltage of 100 V or higher is used in the anodizing treatment, the voltage is reduced at a rate of preferably 20 V/min or lower, more preferably 10 V/min or lower, and most preferably 5 V/min or lower.

It is preferable to maintain a larger electric current. The electric current is preferably maintained at 10 μA/cm² or higher, more preferably at 30 μA/cm² or higher, and most preferably at 50 μA/cm² or higher.

Regularity of the micropore arrangement is disturbed when the electric current is too low. Accordingly, when the electric current is reduced to less than 10 μA/cm² in the above specified rate, it is preferable to stop the voltage reduction, and resume the voltage reduction after the electric current has reached again the level of 10 μA/cm² or more.

<Other Treatments>

Other treatments may also be performed as desired.

For example, when the structure according to aspect (I) of the present invention is to be used as a sample stage onto which an aqueous solution is dropped to form a film of the aqueous solution, a hydrophilization treatment may be performed to reduce the water contact angle. The hydrophilization treatment may be carried out by a method commonly known in the art.

When the structure according to aspect (I) of the present invention is used as a sample stage for holding a protein which is denatured or decomposed by an acid, a neutralization treatment may be performed to neutralize the acid that was used in the anodizing treatment and remains on the aluminum surface. The neutralization treatment may be carried out by a method commonly known in the art.

<Stripping Step>

Stripping step is the step wherein the aluminum member is electrolyzed in an aqueous acid solution by using the aluminum member for the cathode to thereby strip the anodized layer from the aluminum substrate so as to produce a structure composed of the anodized layer with a plurality of recesses. As described above, the aluminum member is used in the electrolysis of the stripping step for the cathode, and since such use of the aluminum member for the cathode is “reverse” to the use of the aluminum member for the anode in the electrolysis of the anodizing treatment, the electrolysis of this step is hereinafter referred to as the “reverse electrolysis”.

In the stripping step, hydrogen is generated by the reverse electrolysis at the boundary between the anodized layer and the aluminum substrate in the aluminum member. This hydrogen reduces the barrier layer of the anodized layer at the boundary with the aluminum substrate, and the barrier layer dissolves as aluminum ions in the aqueous acid solution used as the electrolyte solution. As a consequence, the anodized layer and the aluminum substrate are separated from each other at their boundary.

In the reverse electrolysis, the aluminum member is used for the cathode, and electric power is applied to the member from its aluminum substrate side.

The anode used is not particularly limited, and exemplary anodes used include Pt-plated Ti electrode, Pt electrode, and carbon electrode.

The aqueous acid solution used in the reverse electrolysis preferably has a pH of 1 to 7, more preferably a pH of 2 to 6, and most preferably a pH of 2.5 to 5.5. The aqueous acid solution has an electric conductivity of preferably 0.01 to 100 mS/cm, and more preferably 0.1 to 50 mS/cm.

When the aqueous acid solution has a pH and an electric conductivity in such range, the aluminum substrate is less likely to undergo corrosion and any residual layer will hardly be present on the aluminum substrate. This facilitates the stripping.

When the electric conductivity of the aqueous acid solution is too low, electric current may not take minimum value. In such a case, ion concentration of the aqueous acid solution is preferably increased to enable occurrence of the minimum value of the electric current. On the other hand, when the ion concentration of the aqueous acid solution is too high, electric current takes minimum value indeed. However, electric current will be at the minimum value only for a short time and then increase rapidly, becoming hard to control. In addition, corrosion occurs when the current is at the minimum value for an excessively long time.

Preferable examples of the acid used in the aqueous acid solution include oxalic acid, sulfuric acid, and phosphoric acid.

A metal salt compound which brings about an acid solution when dissolved in water or an organic compound which brings about an acid solution when dissolved in water may also be used Examples of the metal salt compound which brings about an acid solution when dissolved in water include aluminum oxalate, aluminum sulfate, aluminum lactate, aluminum fluoride, and aluminum borate.

The organic compound which brings about an acid solution when dissolved in water is preferably a carboxylic acid. Preferred examples of the carboxylic acid include saturated aliphatic dicarboxylic acids such as adipic acid; unsaturated aliphatic dicarboxylic acids such as maleic acid; aromatic monocarboxylic acids such as benzoic acid; aromatic dicarboxylic acids such as phthalic acid; and aromatic hydroxy acids such as salicylic acid.

In addition, a salt which brings about a neutral solution when dissolved in water, namely a neutral salt, is usable. Preferred examples of the neutral salt include carbonates such as ammonium carbonate and borates such as ammonium borate.

When a neutral salt is used, it is preferable to add a fluoride, a carbonate derivative, or an acid amide as an additive to prepare a mixed bath as the electrolyte solution. Exemplary fluorides include ammonium fluoride, and exemplary carbonate derivatives include guanidine carbonate, urea, and formaldehyde. Exemplary acid amides include acetamide.

Among these, oxalic acid, aluminum oxalate, sulfuric acid, aluminum sulfate, and mixture thereof are preferable, and aluminum sulfate and sulfuric acid are particularly preferable in view of availability and ease of the waste water disposal.

It is also preferable to use an aqueous acid solution of the same type as the electrolyte solution used in the anodizing treatment as described above. Use of such solution enables the anodizing treatment and the reverse electrolysis to be carried out in the same electrolytic cell, and if they are carried out in different electrolytic cells, the adverse effect of introducing a new solution to the reverse electrolytic cell can be avoided.

The conditions for the reverse electrolysis is not unconditionally determined since the conditions vary with the type of the electrolyte solution used.

Preferred concentration of the electrolyte solution is, for example, 0.4 to 10% in the case of aqueous solution of oxalic acid, 2 to 20% in the case of aqueous solution of sulfuric acid, and 0.4 to 5% in the case of aqueous solution of phosphoric acid.

It is general that the temperature of the electrolyte solution is preferably 0 to 50° C., and more preferably 10 to 35° C.

The current density is preferably 0.1 to 200 A/dm², more preferably 0.3 to 50 A/dm², and most preferably 0.5 to 10 A/dm². When the current density is within such range, uneven stripping can be avoided and uniform stripping can be realized.

The voltage is preferably 5 to 500 V, and more preferably 10 to 240 V. When the reverse electrolysis is conducted immediately after the anodizing treatment, the reverse electrolysis at a constant voltage is preferably conducted by using the voltage used in the anodizing treatment.

It is also preferable that the reverse electrolysis is conducted by repeating on-off control of electric current while keeping a DC voltage constant or, alternatively, while intermittently changing a DC voltage. When the voltage is intermittently changed, the voltage is preferably decreased step by step.

The electrolysis is preferably conducted for a time in the range of 1 to 500 seconds, and more preferably 10 to 120 seconds.

Such ranges as above are preferable since stripping of the barrier layer of the anodized layer off the aluminum substrate will be facilitated, and regularity of the recesses in the anodized layer will be improved. When the quantity of electricity is too much or the electrolysis time is too long, boundary between the barrier layer of the anodized layer and the aluminum substrate will be heated to an excessively high temperature, and the resulting structure may be deformed with reduced regularity of the recess arrangement.

The reverse electrolysis is preferably carried out by monitoring the current value, and preferably terminated when the electric current has a value larger than a minimum value by 30% or less, and more preferably, when the electric current has a value in the vicinity of the minimum value. In such a case, stripping will be facilitated, and surface properties of the anodized layer and the aluminum substrate after the stripping will be excellent.

The aluminum substrate produced by the stripping step may have the anodized layer with a thickness of not more than 0.2 μm remaining in the area of up to 10% of the stripped surface. When the aluminum substrate is used, presence of such residual anodized layer is not desirable.

Accordingly, such residual anodized layer is preferably removed by conducing a chemical treatment after the reverse electrolysis, and in particular, by bringing an acidic or alkaline aqueous solution into contact with the remaining anodized layer.

Exemplary acidic aqueous solutions used in such chemical treatment include aqueous solution of phosphoric acid, aqueous solution of sulfuric acid, aqueous solutions of nitric acid, aqueous solution of oxalic acid, and mixed aqueous solution of chromic acid and phosphoric acid, and among these, the preferred is the mixed aqueous solution of chromic acid and phosphoric acid.

The acidic aqueous solution preferably has a pH of 0.3 to 6, more preferably 0 to 4, and most preferably 2 to 4.

The acidic aqueous solution is preferably at a temperature of 20 to 60° C., and more preferably 30 to 50° C.

The chemical treatment is preferably conducted for a time of 1 second to 6 hours, more preferably for 5 seconds to 3 hours, and most preferably for 10 seconds to 1 hour.

Exemplary alkaline aqueous solutions used in the chemical treatment include aqueous solutions of sodium hydroxide, of sodium carbonate, and of potassium hydroxide.

The alkaline aqueous solution preferably has a pH of 10 to 13.5, and more preferably 11 to 13.

The alkaline aqueous solution is preferably at a temperature of 10 to 50° C., and more preferably 20 to 40° C.

The chemical treatment is preferably conducted for a time of 1 second to 10 minutes, and more preferably for 2 seconds to 1 minute, and most preferably for 3 to 30 seconds.

When the anodized layer partly remains after the stripping step, the anodizing treatment and the stripping step may be alternately repeated until the remaining anodized layer is completely removed.

When the anodized layer is stripped off the aluminum substrate by such method, regularity of the recess arrangement on the aluminum substrate side of the layer is not disturbed, and this is advantageous in the case of the second mode in aspect (I) of the present invention as described later.

Exemplary preferable conditions for the reverse electrolysis are as described bellow.

<Preferable Conditions 1>

Cathode: an anodized layer with a thickness of 60 μm, a pore diameter 35 nm, a coefficient of variation in pore diameter of 15%, and a micropore interval of 63 nm produced by anodization in aqueous solution of oxalic acid at a concentration of 0.3 mol/L and at a temperature of 17° C. which is carried out at a voltage of 40 V for a treatment time of 60 minutes.

Anode: carbon electrode.

Electrolyte solution: an aqueous solution of aluminum sulfate at a concentration of 0.04 g/L (calculated in terms of aluminum ion), a pH of 3.8, an electric conductivity of 0.6 ms/cm, and a temperature of 33° C.

Voltage: 40 V (set voltage).

Current density: 5 A/dm² (1 A/dm² at minimum)

Treatment time: 40 seconds (at minimum)

In the method according to the first mode of the present invention, a markedly shorter time is required for the stripping step compared to the conventional layer removal step wherein the layer is dissolved by a mixed aqueous solution of chromic acid and phosphoric acid. Therefore, the method according to the first aspect of the present invention is capable of producing the structure at a high efficiency.

Moreover, the mixed aqueous solution of chromic acid and phosphoric acid has to be replaced with a fresh solution since dissolution ability of the solution is rapidly lost when the content of aluminum oxide exceeds 15 g/L in terms of Al₂0₃ in the layer removal step. Such an anodized layer with a low coefficient of variation in the pore diameter as aimed at in the present invention is generally thick, and a large amount of aluminum oxide dissolves in each treatment cycle, and therefore, the solution undergoes a severe deterioration.

In contrast, in the present invention, the anodized layer is stripped off the aluminum substrate in solid state at the boundary between the anodized layer and the aluminum substrate, and therefore, the anodized layer can be easily separated by using, for example, a filter, and the aqueous acid solution used in the reverse electrolysis is not deteriorated.

Accordingly, the time and the amount of the aqueous acid solution required for the stripping step of the present invention is by far less than the conventional layer removal step wherein the layer is dissolved by a mixed aqueous solution of chromic acid and phosphoric acid.

In the stripping step, the barrier layer is dissolved by the reverse electrolysis as described above to produce a structure composed of the anodized layer having a plurality of recesses.

The stripping step also leaves the aluminum substrate having a plurality of recesses, from which the anodized layer have been stripped off, and this aluminum substrate having a plurality of recesses is used in the second mode of the present invention, which is described below by referring to the drawing.

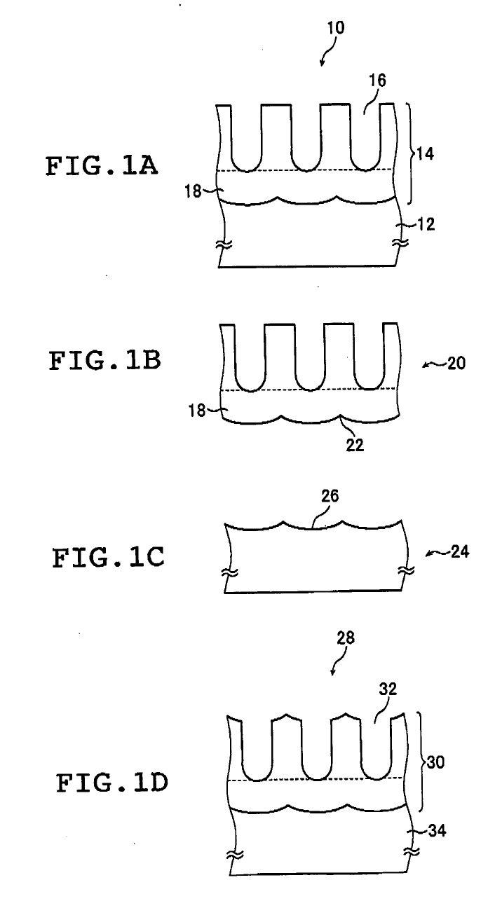

FIGS. 1A through 1D are diagrams illustrating the method for producing a structure according to aspect (I) of the present invention.

FIG. 1A is a schematic cross sectional view of the aluminum member before the stripping step. As shown in FIG. 1A, an aluminum member 10 comprises an aluminum substrate 12 and an anodized layer 14 present on the surface of the aluminum substrate 12. The anodized layer 14 has micropores 16, and a barrier layer 18 as being the part of the anodized layer 14 under the micropores 16.

FIGS. 1B and 1C are schematic cross sectional views of a structure and an aluminum substrate produced by the stripping step, respectively.

The structure 20 shown in FIG. 1B is produced by dissolution of the barrier layer 18 in the anodized layer 14 of the aluminum member 10 shown in FIG. 1A, and is composed of the anodized layer having a plurality of recesses 22.

The aluminum substrate 24 shown in FIG. 1C is produced by dissolution of the barrier layer 18 in the anodized layer 14 of the aluminum member 10 shown in FIG. 1A, and it has a plurality of recesses 26.

The second aspect of aspect (I) of the present invention is directed to a method for producing a structure comprising: a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to obtain the aluminum substrate with a plurality of recesses; and an anodizing step in which the aluminum substrate with a plurality of recesses is anodized to produce a structure composed of the aluminum substrate with a plurality of recesses that is provided on its surface with an anodized layer containing micropores.

The stripping step in the second mode of the present invention is carried out by the same procedure as the stripping step of the first mode of the present invention.

<Anodizing Treatment Step>

According to the second mode of the present invention, an anodizing treatment step is carried out after the stripping step.

The anodizing treatment step is a step in which the aluminum substrate with a plurality of recesses produced in the stripping step is subjected to anodizing treatment to produce a structure composed of the aluminum substrate that is provided on its surface with an anodized layer containing micropores.

In the aluminum substrate with a plurality of recesses produced in the stripping step, the shape at the bottom of the barrier layer under the most regularly arranged micropores corresponds to the shape of the recesses at the surface of the aluminum substrate (See FIG. 1C). Therefore, the recesses on the aluminum substrate have substantially spherical concave shape, and the recesses are regularly arranged as in the case of the micropores.

The anodizing treatment in this step may be carried out by a method commonly used in the art, and more particularly, in a similar manner to the anodizing treatment used in producing the aluminum member.

According to a preferred embodiment, the electrolyte solution used is preferably the same as the one used in the reverse electrolysis as described above. Use of such electrolyte solution enables the reverse electrolysis and the anodizing treatment step to be carried out in the same electrolytic cell, and if they are carried out in different electrolytic cells, the adverse effect of introducing a new solution to the anodizing cell can be avoided.

In the anodizing treatment step, the regularly arranged recesses at the aluminum substrate surface serve as the starting points of the anodizing treatment to form an anodized layer having regularly arranged micropores.

As a consequence, a structure composed of the aluminum substrate that is provided on its surface with an anodized layer having regularly arranged micropores is produced in this anodizing treatment step.

FIG. 1D is a schematic cross sectional view of the structure produced in the anodizing treatment step. FIG. 1D shows a structure 28 produced by subjecting the aluminum substrate 24 shown in FIG. 1C to anodizing treatment to thereby form an anodized layer 30. In the anodizing treatment, recesses 26 on the aluminum substrate 24 serve as the starting points for forming of micropores 32. The structure 28 is therefore composed of an aluminum substrate 34 which is provided on its surface with an anodized layer 30 containing the micropores 32.

In the method according to the second mode of the present invention, a markedly reduced time is required for the stripping step compared to the conventional layer removal step wherein the layer is dissolved by a mixed aqueous solution of chromic acid and phosphoric acid. Therefore, the method according to the second mode of the present invention is capable of producing the structure at a high efficiently.

<Structure>

Both the structure produced by the method according to the first mode of the present invention that is composed of the anodized layer having a plurality of recesses and the structure produced by the method according to the second mode of the present invention that is composed of the aluminum substrate provided on its surface with an anodized layer having micropores have regularly arranged recesses or micropores, and therefore, these structures can be used in a wide variety of applications.

For example, the structures can be used as a sample stage for Raman spectroscopic analysis when a plurality of recesses or micropores are filled with a metal.

The structures can also be used as a mold for nano-printing.

<Sealing Treatment>

In the practice of the invention, the metal used in sealing treatment is an element having metal bonds that include free electrons, and is not subject to any particular limitation. However, a metal in which plasmon resonance has been recognized is preferred. Of these, gold, silver, copper, nickel and platinum are known to readily give rise to plasmon resonance (Gendai Kagaku (Contemporary Chemistry), pp. 20-27 (September 2003)), and are thus preferred. Gold and silver are especially preferred because of the ease of electrodeposition and colloidal particle formation.

The method used in the sealing treatment is not particularly limited, and the sealing treatment can be carried out by any suitable method known in the art.

Examples of preferred techniques include electrodeposition, and a method which involves applying a dispersion of metal colloidal particles to the structure according to the aspect (I) of the present invention, followed by drying. The metal is preferably in the form of single particles or agglomerates.

An electrodeposition method known in the art may be used. For example, in the case of gold electrodeposition, use may be made of a process in which the aluminum member is immersed in a 30° C. dispersion containing 1 g/L of HAuC14 and 7 g/L of H₂SO₄ and the electrodeposition is carried out at a constant voltage of 11 V (adjusted with a slidax) for 5 to 6 minutes.

An example of an electrodeposition method which employs copper, tin and nickel is described in detail in Gendai Kagaku (Contemporary Chemistry), pp. 51-54 (January 1997). Use can be made of this method as well.

The dispersions employed in sealing treatment using metal colloidal particles can be obtained by a method known in the art. Illustrative examples include methods of preparing fine particles by low-vacuum evaporation and methods of preparing metal colloids by reducing an aqueous solution of a metal salt.

The metal colloidal particles have a mean particle size of preferably 1 to 200 nm, more preferably 1 to 100 nm, and even more preferably 2 to 80 nm.

The dispersion medium employed in the dispersion is preferably water. Use can also be made of a mixed solvent composed of water and a solvent that is miscible with water, such as an alcohol, illustrative examples of which include ethyl alcohol, n-propyl alcohol, i-propyl alcohol, 1-butyl alcohol, 2-butyl alcohol, t-butyl alcohol, methyl cellosolve and butyl cellosolve.

No particular limitation is imposed on the technique used for application of the dispersion of metal colloidal particles. Suitable examples of such techniques include bar coating, spin coating, spray coating, curtain coating, dip coating, air knife coating, blade coating, and roll coating.

Preferred examples of the dispersions that may be employed in the sealing treatment which use metal colloidal particles include dispersions of gold colloidal particles and dispersions of silver colloidal particles.

Dispersions of gold colloidal particles that may be used include those described in JP 2001-89140 A and JP 11-80647 A. Use can also be made of commercial products.

Dispersions of silver colloidal particles preferably contain particles of silver-palladium alloys because these are not affected by the acids which leach out of the anodized layer. The palladium content in such a case is preferably from 5 to 30 wt %.

After application of the dispersion, suitable cleaning is performed using a solvent such as water. As a result of such cleaning, only the particles filled into the recesses or micropores remain, and the particles that have not been filled into the recesses or micropores are removed.

The amount of metal remaining attached after the sealing treatment is preferably 100 to 500 mg/m².

The surface porosity after the sealing treatment is preferably 20% or less. The surface porosity after the sealing treatment refers to the ratio of the total area of the openings of unsealed recesses or micropores to the area of the structure surface, and the surface porosity within the above-specified range provides further enhanced localized plasmon resonance.

At a pore diameter of 50 nm or more, the use of a sealing method employing metal colloidal particles is preferred. At a pore diameter of less than 50 nm, the use of an electrodeposition process is preferred. Suitable use can also be made of both in combination.

The thus-obtained structure after the sealing treatment has a plurality of recesses or micropores sealed with a metal, and the metal is present as particles on the structure surface.

In general, the distance between the metal particles is preferably small for increasing a Raman enhancing effect, but the optimum distance is influenced by the size or shape of the metal particles. Further, depending on the molecular weight of the substance or the viscosity of the liquid used as a sample fox Raman spectroscopic analysis, a problem may be caused in that the substance or the liquid does not sufficiently penetrate through the gap between the metal particles.

Accordingly, the distance between the metal particles cannot be unconditionally determined. The distance, however, is preferably in the range of 1 to 400 nm, more preferably 5 to 300 nm, and most preferably 10 to 200 nm. The distance within the above range provides a large Raman enhancing effect and, at the same time, less causes a problem of preventing the substance used as a sample from penetrating through the gap between the metal particles.

Here, “distance between the metal particles” refers to the shortest distance between the surfaces of the adjacent particles.

<Raman Enhancing Effect by Localized Plasmon Resonance>

The Raman enhancing effect is a phenomenon in which the Raman scattering intensity of a molecule adsorbed on a metal is enhanced by about 10⁵ to 10⁶ times, and this effect is called surface enhanced Raman scattering (SERS). Gendai Kagaku (Contemporary Chemistry), pp. 20-27 (September 2003), supra describes a Raman enhancing effect by localized plasmon resonance using metal particles of gold, silver, copper, platinum, nickel, or the like.

The sealed structure can provide localized plasmon resonance with an intensity higher than that of prior art, and use of such structure in the Raman spectroscopic analysis provides further increased Raman enhancing effect. Accordingly, the sample holder for Raman spectroscopic analysis employing the sealed structure is useful.

The usage of the sample holder for Raman spectroscopic analysis using the sealed structure is the same as that of a conventional sample holder for Raman spectroscopic analysis. To be specific, property of a substance in the vicinity of the metal held on the sample holder for Raman spectroscopic analysis using the sealed structure is detected by irradiating the sample holder with a light beam and measuring the Raman scattering intensity of the reflected light or transmitted light.

<Nano-Printing>

The structure according to aspect (I) of the present invention can be used as a mold for nano-printing. More specifically, a resin or the like may be filled into the recesses or micropores in the structure of the present invention and then solidified to produce a substrate having a plurality of projections, and such substrate having a plurality of projections can also be used, for example, as an optical device.

[Aspect (II)]

Next, aspect (II) of the present invention is described in detail.

The method for producing a nanostructure according to aspect (II) of the present invention is a method for producing a nanostructure comprising the steps of performing polishing on an aluminum substrate having an aluminum purity of at least 99.9% at least by mechanical polishing to an arithmetical mean roughness Rₐ of up to 0.1 μm and a glossiness of at least 60%, and further performing anodizing on the aluminum substrate to thereby produce a nanostructure provided in its surface with micropores.

<Aluminum Substrate>

The aluminum substrate used in the production method according to aspect (II) of the present invention has an aluminum purity of 99.9% or higher. An aluminum substrate having a higher aluminum purity has an increased regularity after anodization as well as an increased size of the area with regular arrangement (in terms of average pore interval), and therefore, the aluminum substrate preferably has the highest possible aluminum purity when the aluminum substrate is used for an electromagnetic device. In this regard, an aluminum material having an aluminum purity of preferably 99.99% or higher, more preferably 99.995% or higher, and still more preferably 99.999% or higher is known.

A commercially available aluminum sheet having an aluminum purity of 99.9 to 99.99% is generally associated with rolling streaks but mostly with no blisters. However, an aluminum sheet having an aluminum purity in excess of 99.99% is often custom produced by using a small width experimental machine, and therefore, usually associated with different degrees of blisters.

An aluminum having an aluminum purity of 99.99 to 99.999 wt % is generally called a high purity aluminum, and an aluminum having an aluminum purity of 99.999 wt % or higher is called an ultra high purity aluminum.

The aluminum substrate is produced by repeated melting for purification in a melting furnace, and in the melting furnace, the molten metal is agitated by using a gas such as air and inert gas. As a consequence, the gas is trapped in the metal, and the metal has to be degassed under reduced pressure. In the case of high purity material having an aluminum purity in excess of 99.99%, the metal needs severe agitation for floating of trace amounts of impurities to the surface, and this results in a higher content of bubbles in the resulting metal, and hence, in insufficient degassing.

When such aluminum including bubbles is rolled, raised parts called “blisters” with a diameter of about 50 μm to 2 mm, and in particular, a diameter of about 0.1 to 1 mm, and a depth of about 0.1 to 20 μm and in particular, a depth of about 0.3 to 10 μm are generated on a rolled product. Density of the blisters is generally in the range of several blisters to several hundred blisters per square decimeter. The resulting product is also associated with the rolling streaks.

<Surface Treatment>

The methods used for treating a metal surface are generally classified into mechanical treatments, chemical treatments, and electrochemical treatments. Among these, mechanical treatment refers to a treatment in which a metal surface is mechanically abraded generally by using an abrasive with a high degree of hardness placed between the object to be polished and a polisher and moving the object and the polisher in relation to each other. The resulting metal surface varies with the type and particle size of the abrasive and the polisher used. Chemical treatment refers to the smoothing of oxide film on a metal surface or the metal surface itself with an aqueous acid or alkali solution.

In aspect (II) of the present invention, a chemical treatment or an electrochemical treatment may be conducted simultaneously with or separately from the mechanical treatment as long as the mechanical treatment is conducted.

The inventors of the present invention found that, among various methods known as for treating a metal surface, at least mechanical polishing is required in order to remove the relatively large surface irregularities such as “blisters” or “rolling streaks”.

In addition, in aspect (II) of the present invention, the substrate is preferably subjected to auxiliary chemical polishing and electrochemical polishing treatments as will be described later after the mechanical polishing treatment as described below.

<Mechanical Polishing>

Mechanical polishing is a method in which the substrate is polished by grinding the substrate with sharp edges of an abrasive. In the mechanical polishing, an abrasive-containing medium such as abrasive slurry (a mixture of water and an abrasive) is embedded in a support such as cloth, paper, or metal, or the abrasive-containing medium is supplied between the substrate as an object to be polished and the support as a polisher for frictional contact of the abrasive with the substrate. This method makes it possible to treat a large area at once at a high grinding performance, and also to remove deep defects. When the substrate is thin, the substrate generally needs to be embedded in a resin or adhered to a metal block to thereby facilitate polishing of the substrate. Particularly when mirror finished, the surface of the substrate is subjected to a polishing called buff polishing using a special polishing cloth and abrasive.

(1) Fine Polishing

Fine polishing is preferably conducted by using a polisher such as a polishing paper or cloth produced by applying an abrasive such as SiC, diamond, or alumina onto a water resistant paper or cloth. Exemplary such polishers include a polishing paper produced by embedding SiC powder in a water resistant paper, a fine polisher produced by embedding a diamond powder in a metal, and a fluffed cloth (commonly called “buff”) for use in combination with a slurry or paste of an abrasive in water or a chemical. The grit of the abrasive may vary from #80 (particle size, 200 μm) up to #4000 (particle size, 4 μm).

The abrasive or the polishing cloth is preferably changed from the one having a lower grit number (larger particle size) to the one having a higher grit number (smaller particle size) step by step. While buffing can be conducted by using a coarse abrasive without fine polishing, fine polishing using a water resistant paper or cloth onto which the abrasive is applied is preferably conducted since the coarse abrasive remaining on the surface may cause scratches. The water resistant paper or cloth is preferably changed with the change of the abrasive.

Various commercial polishers including the following can be used for the fine polishing.

Polishing cloths DP-Net with a particle size of 6 to 45 μm manufactured by Marumoto Struers

Polishing cloths DP-Nap with a particle size of 0.25 to 1 μm manufactured by Marumoto Struers

Water resistant polishing papers of a #80 to #1500 grit manufactured by Marumoto Struers

(2) Buff Polishing

Buff polishing uses a buff formed from a cotton cloth, sisal cloth, wool fiber, or the like, which is caused to rotate at a high speed. The rotating buff may have an abrasive fixed to its peripheral surface with an adhesive such as glue or, alternatively, held temporarily on its surface. Against the rotating buff as such, an article is pressed to thereby mechanically grind and smooth the surface of the article.

a) Polishing Machine

A buff polishing machine is a polishing machine in which a buff is attached at an end of a machine shaft, and caused to hold an abrasive on its peripheral surface. The polishing is conducted by rotating the buff as such at a high speed. While manual polishing is also possible, automatic polishing can be carried out by using the polishing machine in combination with an adequate jig.

Various commercial polishing machines including the following can be used as the buff polishing machine.

LaboPol-5, RotoPol-35, and MAPS manufactured by Marumoto Struers

b) Buff

Exemplary buffs include fabric buffs such as sewn buffs, stitched buffs, loose buffs, bias buffs and sisal buffs, and other buffs such as flap wheels, nonwoven wheels and wire wheels, which are used in adequate applications. The preferred is use of a napped cotton buff.

Various commercial buffs including the following are usable.

Polishing cloths No. 101 (wool), No. 102 (cotton), No. 103 (synthetic fiber), and No. 773 (blend of cotton and synthetic fibers) manufactured by Marumoto Struers

c) Abrasive

Buffing abrasive refers to a homogeneous mixture of a powder abrasive having a relatively small particle size as the main component and a grease or other suitable component constituting a medium.

Various commercial abrasives can be used as the buffing abrasive.

c-1) Grease-Based Abrasive

Grease-based abrasive refers to an abrasive produced by kneading fine abrasive particles with a grease and solidifying the resulting mixture, and such abrasive is mainly used for mid-stage polishing and finish polishing. The greases commonly used include stearic acid, paraffin, tallow, and rosin.

When the grease-based abrasive is pushed against the buff, the grease melts by the frictional heat, and the abrasive particles move onto the buff surface along with the molten grease. When a metal article is pressed against such buff, the grease forms an oil film on the surface of the metal, and, in consequence, unnecessary biting of the abrasive particles into the metal surface is prevented to facilitate smoothing of the metal surface.

Examples of the grease-based abrasive include emery paste, tripoli, crocus, lime, green rouge, red rouge, white rouge, and grease stick. Among these the preferred are tripoli (main component, SiO₂; Mohs hardness, 7), quick lime (main component, CaO; Mohs hardness, 2), green rouge (main component, Cr₂O₃; Mohs hardness, 6), and white rouge (main component, Al₂O₃; Mohs hardness, 9).

c-2) Liquid Abrasive

A liquid abrasive is an abrasive produced for use in an automatic buff polishing machine. Since the abrasive is in liquid form, it can be automatically fed to the polishing machine.

Examples of conventional liquid abrasives include those containing SiC, diamond, and alumina powder. The liquid abrasive is used in the automatic buff polishing machine, for example, by spraying the liquid abrasive from a nozzle of a spray gun and by controlling intermittent opening and closing of the nozzle with a timer.

Particle size of an abrasive is generally indicated by grit number, and an abrasive with a higher grit number has a smaller particle size (see Table 1 below).

TABLE 1

| Grit | Mean particle size [μm] |
|---|---|
| #80 | 300 |
| #240 | 80 |
| #400 | 40 |
| #800 | 20 |
| #1000 | 16 |
| #1500 | 10 |
| #2000 | 7.9 |
| #3000 | 5 |
| #4000 | 3.1 to 4.5 |
| #8000 | 1.5 to 2 |

Polishing is generally carried out by starting from the coarsest abrasive, and sequentially changing the abrasive to a finer abrasive. Mirror-like gloss starts to appear on the surface polished with an abrasive having a grit of around #1000, and the surface visually reaches mirror finished state when it is polished with an abrasive having a grit of around #1500 or higher.

Various abrasives having a mean particle size of about 0.1 to 100 μm are commercially available, including the following abrasives.

Diamond suspensions DP-Spray having a particle size of 0.25 to 45 μm manufactured by Marumoto Struers Alumina suspensions No. 100 (particle size, 1 μm) to No. 2000 (particle size, 0.06 μm) manufactured by Meller

c-3) Polishing Aid

Emery is adhered to the cloth buff, for example, by a glue, cement, or the like. Glue becomes a viscous liquid when dissolved in a hot water. Cement is sodium silicate blended with a synthetic resin, and adheres the emery to the buff as in the case of glue.

When surface irregularities with large width and depth (several hundred micrometers to several millimeters) are removed by mechanical polishing, the polishing may be conducted by such methods as set forth in Table 2 below. The mechanical polishing is preferably conducted at a peripheral speed of 1800 to 2400 m/min.

TABLE 2

| | | | | | Rₐ after |
|---|---|---|---|---|---|
| Type of | Form of | Type of | | | polishing |
| polishing tool | polishing tool | abrasive | Grit | Polisher | [μm] |
| Polishing | Sheet | Garnet, | #80 to #10000 | Cloth | 0.1 to 2 |
| cloth or | | alumina, | | | |
| paper | | zirconia, SiC | | | |
| Polishing | Sheet | Alumina, | #500 to #10000 | PET | 0.1 to 1.5 |
| film | | SiC, | | | |
| | | diamond | | | |
| Flap | Wheel | Alumina, | #500 to #1000 | Cloth | 0.3 to 1.5 |
| wheel | | SiC | | | |
| Polishing | Wheel, | Alumina, | #100 to #3000 | Nylon, | 0.2 to 1.5 |
| brush | roll, | SiC | | aramid | |
| | etc. | | | | |
| PVA | Wheel, | Alumina | #3000 to #10000 | Cloth | 0.1 to 0.3 |
| grinder | roll, | | | | |
| | etc. | | | | |
| Buff | Wheel, | Alumina | #3000 to #10000 | Fluffed | 0.1 to 0.3 |
| | rotating | | | cloth | |
| | sheet | | | | |

Among others, use of a polishing cloth, polishing paper, and buff is preferable in view of availability and versatility.

When the entire polishing is conducted by using buffs, it is preferable that rough polishing (grit of up to #400) is conducted with a sisal cloth or cotton twill, mid-stage polishing (grit of #400 to #1000) with a plain weave cotton or rayon, and finish polishing (grit of #1000 or higher) with a calico, broadcloth, flannel, felt, oxhide or the like. When the abrasive is changed into a new abrasive with different grit number, the cloth should be replaced by a new one and the polished surface be fully cleaned beforehand.

For further detail, see “New Practical Technology for Polishing” published by Ohmsha, Ltd., 1992, 1st edition, pages 55 to 93.

The mechanical polishing as described above may also be conducted by electrolytic-abrasive polishing.

<Electrolytic-Abrasive Polishing>

Electrolytic-abrasive polishing is a method in which a direct current is applied at a current density of preferably 0.05 to 1 A/cm², and more preferably in the order of 0.1 A/cm² to an article while abrasively polishing the article by pressing the article against the polisher at a pressure of about 5 to 20 kPa (50 to 200 g/cm²). When an electrolysis is conducted at such a low current density, in general, metal dissolution hardly occurs due to formation of a thick passivated film on the surface to be processed. However, when the passivated film is frictionally removed by the abrasive particles, metal dissolution is promoted at the exposed area, and the current efficiency rapidly increases to the level of tens to a hundred percent. Since micro-ordered areas rising from the surface are selectively removed by the frictional abrasion with the abrasive particles and the electrolytic dissolution of the metal rapidly increases in such areas while areas not rising from the surface remain substantially intact, surface roughness of the article is rapidly improved.

The abrasive suitably used may be an abrasive commonly used in the art, or colloidal silica or colloidal alumina.

Specifically, high purity colloidal silica PL series such as PL-1 (primary particle size, 15 nm: secondary particle size, 40 nm), PL 3 (primary particle size, 35 nm; secondary particle size, 70 nm), PL-7 (primary particle size, 70 nm; secondary particle size, 120 nm), and PL-20 (primary particle size, 220 nm; secondary particle size, 370 nm) manufactured by Fuso Chemical Co., Ltd. and PLANERLITE series manufactured by Fujimi Incorporated may suitably be used.

(1) Oscar-Type Polishing Machine

Use of an Oscar-type polishing machine is preferable when the surface is to be provided with a good flatness in addition to a finely mirror-finished state.

Oscar-type polishing machine is an apparatus which has been used in polishing an optical element and so forth. In the Oscar-type polishing machine, the article moves in relation to the rotation of the surface plate, and a high precision in shape is easily realized due to the reduced difference in the amount of polishing by the location. On the other hand, electrolytic-abrasive polishing is advantageous in the efficiency of improving the surface roughness. Combination of the use of Oscar-type polishing machine with the electrolytic-abrasive polishing enables high quality mirror finishing with high precision.

The electrolytic-abrasive polishing can be accomplished in accordance with the details described in JP 3044377 B1 and JP 3082040 B1.

The method described in detail in “New Practical Technology for Polishing” (published by Ohmsha, Ltd., 1992, 1st edition, pages 55 to 93) can also be used.

In aspect (II) of the present invention, an aluminum substrate having an arithmetical mean roughness Rₐ of up to 0.1 μm and a glossiness of 60% or higher can be produced by the mechanical polishing as described above.

(Arithmetical Mean Roughness Rₐ)

Arithmetical mean roughness Rₐ of a metal surface is generally determined by selecting a plurality of measurement points in the transverse direction, namely, the direction perpendicular to the direction of rolling; measuring the surface roughness over a standard length in the direction of rolling at the selected measurement points; and calculating the average.

In aspect (II) of the present invention, it is preferable that the measurement of the arithmetical mean roughness Rₐ is conducted by cross section curve method in which the surface profile indicated in the cross section perpendicular to the measured surface is determined, namely, by using a contact-probe profilometer when Rₐ is 1 μm or higher and using an atomic force microscope (AFM) when Rₐ is less than 1 μm to obtain the cross section curve.

In JIS-B601-1994, roughness is evaluated from part of the roughness curve which is sampled by an evaluation length defined on the basis of the standard length L, that is to say, constituted of several (five, for instance) sequential standard lengths. The standard length is to be the same as the cut off value. Various parameters of roughness are determined within each standard length, and the averages in individual parameters are calculated for all standard lengths as the measurements.

In aspect (II) of the present invention, the arithmetical mean roughness Rₐ is the average of the measurements which are obtained in the rolling direction and the direction perpendicular to the rolling direction.

(Glossiness)

In JIS Z 8741, a glass surface having a refractive index of 1.567 (specular reflectance of 10% at an angle of incidence of 60 degrees) over the entire visible region of wavelength is defined to have a glossiness of 100(%). However, a glass surface having such refractive index of 1.567 is easily affected by moisture and the like, and the reference surface actually used is a surface having a refractive index of about 1.500 (glossiness of 90%) (the absolute value is corrected in each measurement by using the reference plate having a glossiness of 90% as 90% reference).

Glossiness is generally measured at a smaller angle for the article having a higher glossiness and at a larger angle for the article having a lower glossiness. In JIS standards, use of angles of 20 degrees, 45 degrees, 60 degrees, 75 degrees, and 85 degrees are defined. However, a popular glossmeter is of a type using an angle of 60 degrees since it has a wide measuring range. Such use of single glossmeter is possible because the glossiness measured varies with the measurement angle in a proportional manner, and the glossiness at other angles can be estimated from the glossiness measured at one particular angle without measuring at every angle. According to JIS standards, glossiness can be indicated in terms of percentage, or solely by showing the figure with no “%”.

Glossiness is also called “specular reflectance” and the glossiness is measured at several points in the longitudinal direction parallel to the direction of rolling, and also, at several points in the transverse direction perpendicular to the direction of rolling, and the average is calculated. The glossiness of the aluminum substrate obtained in the method of the present invention is at least 60%, and preferably at least 80% for both longitudinal direction and transverse direction.

The arithmetical mean roughness and the glossiness of the present invention are determined by obtaining the average for the longitudinal direction and the transverse direction in an area of preferably 50 mm² or more, more preferably 400 m² or more, and most preferably 900 mm² or more.

The surface of an aluminum substrate having an arithmetical mean roughness Rₐ Of 0.1 μm or less and a glossiness of 60% or more can be regarded as a substantially mirror finished surface with no visually recognizable defects.

<Chemical Polishing and Electrochemical Polishing>

In the production method according to aspect (II) of the present invention, auxiliary chemical polishing and electrochemical polishing are preferably conducted after the mechanical polishing. In the present invention, an auxiliary polishing refers to a polishing wherein the decrease in Rₐ is up to 50% of the decrease in Rₐ in the mechanical polishing.

(1) Chemical Polishing

Chemical polishing is a method in which surface of the aluminum substrate is dissolved by immersing the aluminum substrate in an alkaline aqueous solution or an acidic aqueous solution. As for the alkaline aqueous solution, it is preferable to use chiefly an aqueous solution of sodium carbonate, sodium silicate, sodium phosphate, or a mixture thereof. An aqueous solution of sulfuric acid, nitric acid, phosphoric acid, butyric acid, or a mixture thereof is used as the acidic aqueous solution.

Examples of the chemical polishing carried out as an auxiliary polishing are as shown in Table 3 below.

TABLE 3

| Type of aqueous | | | |
|---|---|---|---|
| solution (wt %) | Temperature | pH | Time |
| 0.5 to 2% Sodium | Room temperature | 9 to 12 | 10 sec to |
| carbonate | to 50° C. | | 30 min |
| 0.05 to 0.2% Silicate | | | |
| 0.5 to 4% Sodium | Room temperature | 9 to 12 | 10 sec to |
| metasilicate | to 70° C. | | 30 min |
| 0.6 to 1.8% Sodium | 50 to 70° C. | 9 to 12 | 10 sec to |
| carbonate | | | 30 min |
| 0.6% Sodium | | | |
| orthosilicate | | | |
| 0.1 to 0.5% Sodium | 50 to 70° C. | 9 to 12 | 10 sec to |
| carbonate | | | 30 min |
| 0.6 to 1.2% Sodium | | | |
| silicate | | | |

By adequately adjusting the composition of the aqueous solution as described above, the aluminum substrate can be gradually dissolved to reduce Rₐ. Preferred aqueous acid solutions are exemplified by those as shown in Table 4 below.

TABLE 4

| Type of aqueous | | | |
|---|---|---|---|
| solution (wt %) | Temperature | pH | Time |
| 3 to 5% Sulfuric | Room | 0.3 to 1 | 1 to 5 min |
| acid | temperature | | |
| 1 to 3% Nitric acid | Room | 0.6 to 2 | 1 to 5 min |
| | temperature | | |
| 4% Chromic acid | 60° C. | −1 | 1 to 5 min |
| 21% Sulfuric acid | | | |
| 5% Hydrofluoric | Room | 0 | 30 sec to 3 min |
| acid | temperature | | |
| 2.5% Nitric acid | | | |

Also preferred is a mixed aqueous solution of sulfuric acid, nitric acid, phosphoric acid, and butyric acid having a formulation as described in “Surface Treatment of Aluminum” (published by Uchida Rokakuho Publishing Co., Ltd., 1980, 8th edition, page 36, Table 3). Another preferable solution is a mixed solution of concentrated phosphoric acid and fuming nitric acid having copper nitrate added thereto which is used in Alupol method as described in Met. Ind., 78 (1951), 89.

Various methods described in “Handbook of Aluminum Technology” (edited by Japan Light Metal Association and published by Kallos Publishing Co., Ltd., 1996), Table 5.2.15 are also usable. Among these, the preferred is the method using phosphoric acid-nitric acid.

(2) Electrochemical Polishing

Electrochemical polishing is a method in which the aluminum substrate is immersed in an electrolyte solution and an electric power of mainly DC is applied to remove the surface irregularities of the aluminum surface by dissolution. Examples of preferable electrolyte solution include acidic aqueous solutions of hydrogen peroxide, glacial butyric acid, phosphoric acid, sulfuric acid, nitric acid, chromic acid, and sodium dichromate, and mixtures thereof. Additives such as ethylene glycol monoethyl ether, ethylene glycol monobutyl ether, and glycerin may also be used. Use of such additives has the effects of stabilizing the electrolyte solution, and maintaining the electrolyte solution in adequate condition for the electrolysis against change in concentration, change with time, and deterioration by the use.

(3) Electrolytic Polishing

Exemplary conditions for the electrolytic polishing conducted as an auxiliary polishing are as set forth in Table 5 below.

TABLE 5

| | | | | | Electric |
|---|---|---|---|---|---|
| | | Time | | Voltage | current |
| Electrolyte solution | Temp. | [min] | Waveform | [V] | [A/dm²] |
| 15 to 25% Aqueous | up to | 10 to 20 | DC | 50 to 100 | 3 to 5 |
| solution of | 50° C. | | | | |
| perchloric acid | | | | | |
| (specific gravity, | | | | | |
| 1.48) | | | | | |
| 70 to 80% Glacial | | | | | |
| butylic acid | | | | | |
| 40 to 60 vol % | 40 to | 3 to 10 | DC | 10 to 30 | 3 to 60 |
| Phosphoric acid | 70° C. | | | | |
| 5 to 30 vol % | | | | | |
| Sulfuric acid | | | | | |
| 15 to 20 vol % | | | | | |
| Water | | | | | |
| 0 to 35 vol % | | | | | |
| Ethylene | | | | | |
| glycol monoethyl | | | | | |
| ether | | | | | |

Also preferred are the polishing conditions described in “Surface Treatment of Aluminum” (published by Uchida Rokakuho Publishing Co., Ltd., 1980, 8th edition, page 47, Table 6). In addition, various methods described in “Handbook of Aluminum Technology” (edited by Japan Light Metal Association and published by Kallos Publishing Co., Ltd., 1996), Table 5.2.17 are usable.

In view of availability and safety of the solution used, the preferred is the method of Battelle (British Patent No. 526854 (1940) and British Patent No. 552638 (1943)) or the method using phosphoric acid bath (JP 128891 B (application for patent being filed in 1935; JP S13-004757 B).

<Finish Polishing>

In the production method according to aspect (II) of the present invention, the aluminum substrate is preferably further polished by additionally using a chemical mechanical polishing (CMP) method or barrier layer removing method after the mechanical polishing and the auxiliary polishing by the chemical polishing and/or the electrolytic polishing.

(1) CMP Method

CMP method is a combination of mechanical polishing and chemical polishing which is mainly used in semiconductor processing. Aluminum substrate can be polished by the CMP method as long as it has been fully polished to the level of flat mirror surface. In this regard, use of an alumina or silica slurry is popular for a metal such as aluminum, and colloidal alumina or colloidal silica can be used. Examples include high purity colloidal silica PL series manufactured by Fuso Chemical Co., Ltd. and PLANERLITE series manufactured by Fujimi Incorporated.

In the CMP method, adequate amounts of H₂O₂, Fe(NO₃)₂, and KIO₃ are added as additives. These additives are preferably used to prepare an acidic slurry which is generally adjusted to a pH of about 2 to 4 since the metal surface should be polished simultaneously with oxidation of the surface in order to prevent scratching and embedding of the abrasive therein. The abrasive preferably has a primary particle size of 5 nm to 2 μm, and a concentration in the slurry of 2 to 10 vol %. The CMP pad used is preferably a soft pad to prevent scratching. Exemplary pads include CMP pads XHGM-1158 and XHGM-1167 manufactured by Rodel Nitta.

CMP can be accomplished by the method described in “Introduction to Semiconductor Manufacturing Equipment” by Kazuo Maeda published on March, 1999 from Kogyo Chosakai Publishing Co., Ltd. (page 171, FIG. 5.44, Elementals of CMP and equipment used in CMP; and page 172, FIG. 5.45, Constitution of CMP equipment).

The CMP method makes it possible to conduct a high precision polishing. The method, however, requires an expensive installation and complicated steps of selecting the abrasive and additives and setting the polishing conditions. Accordingly, a barrier layer removing method may be used for the finish polishing.

(2) Barrier Layer Removing Method

After the chemical polishing and electrolytic polishing, the substrate is preferably further smoothed by a barrier layer removing method in which a barrier-type anodized layer free from micropores is formed and then removed.

A barrier layer is known to be formed by an electrolysis in an electrolyte solution having a pH of about 4 to 8 near the neutral value. The thus formed anodized layer is uniform and free from micropores.

Exemplary known electrolytic conditions include those set forth in Table 6 below.

Examples of preferable electrolyte solutions include aqueous solutions of a neutral salt such as borate, adipate, phosphate, citrate, tartrate, or oxalate, and mixtures thereof, for example, a mixed aqueous solution of boric acid and sodium borate, or ammonium tartrate. It is also possible to use a neutral aqueous solution obtained by adjusting citric acid, maleic acid, glycolic acid or the like in pH with an alkali such as NaOH.

The electrolysis is preferably conducted at a voltage of 10 to 800 V, and more preferably at 30 to 500 V.

The electrolyte solution preferably has a pH of 4 to 8, and more preferably a pH of 5 to 7.

The electrolysis is preferably terminated before saturation of the voltage in constant current electrolysis, or before substantial stopping of the current flow in constant voltage electrolysis. To be more specific, the electrolysis is preferably conducted for 1 to 30 minutes, and more preferably conducted for 1 to 12 minutes.

The anodized layer preferably has a thickness of 0.1 to 1 μm, and more preferably a thickness of 0.2 to 0.6 μm. The thickness of the layer is known to increase in proportion to the final electrolytic voltage.

TABLE 6

| | | | | | Electric |
|---|---|---|---|---|---|
| Electrolyte | | Time | | Voltage | current |
| solution | Temp. | [sec] | Waveform | [V] | [A/dm²] |
| 0.5 mol/L Boric | 20 to 90° C. | 300 to 1200 | DC | 0 to 1200 | 25 |
| acid | | | | | |
| 0.5 mol/L Boric | 20 to 90° C. | 300 to 1200 | DC | 0 to 1200 | 25 |
| acid | | | | | |
| 0.0005 to 0.05 mol/L | | | | | |
| Sodium borate | | | | | |
| 2 mol/L Boric acid | 20 to 90° C. | 300 to 1200 | DC | 0 to 1200 | 25 |
| 0.005 mol/L | | | | | |
| Ammonium pentaborate | | | | | |
| 150 g/L Ammonium | 20 to 90° C. | 300 to 1200 | DC | 0 to 110 | 25 |
| adipate | | | | | |
| 1.4 g/L Ammonium | 20 to 90° C. | 300 to 1200 | DC | 0 to 110 | 25 |
| dihydrogen | | | | | |
| phosphate | | | | | |

TABLE 7

| | | | | | | Preferable |
|---|---|---|---|---|---|---|
| Electrolyte | | | | | Layer | electrolysis |
| solution | Concentration | pH | Temp. | Voltage | thickness | time |
| Ammonium | 0.27 mol/L | 6.7 | 33° C. | 100 V | 0.15 μm | 1.5 to 10 min |
| tartrate | | | | | | |
| Ammonium | 0.27 mol/L | 6.7 | 33° C. | 200 V | 0.3 μm | 3 to 20 min |
| tartrate | | | | | | |
| Ammonium | 0.1 mol/L | 6.7 | 33° C. | 300 V | 0.4 μm | 4 to 30 min |
| tartrate | | | | | | |
| Ammonium | 0.1 mol/L | 6.7 | 33° C. | 400 V | 0.5 μm | 5 to 40 min |
| tartrate | | | | | | |
| Ammonium | 0.1 mol/L | 6.7 | 33° C. | 500 V | 0.6 μm | 6 to 60 min |
| tartrate | | | | | | |
| Boric acid - | 0.5 mol/L-0.05 mol/L | 4.5 | 20° C. | 100 V | 0.1 μm | 1.5 to 10 min |
| sodium | | | | | | |
| borate | | | | | | |

Removal of the barrier layer is generally conducted by using a mixture of acidic aqueous solutions such as aqueous solutions of phosphoric acid, chromic acid, nitric acid, and 53 sulfuric acid, and the preferred are the aqueous solution used in the chemical polishing and aqueous chromic acid-phosphoric acid solution.

The barrier layer formed is generally known to be thicker in the raised part and thinner in the recessed part, and therefore, the boundary between the aluminum and the anodized layer is led to be flat. Accordingly, a smooth surface is realized after removing the barrier layer.

Method described in “New Theories on Anodized Aluminum” published by Kallos Publishing Co., Ltd., 1997, page 16 may be used for the details.

When the barrier layer formed under the conditions as described above is dissolved to remove by using an aqueous chromic acid-phosphoric acid solution or performing chemical polishing, the mirror finished state of the surface is further improved.

<Barrier Layer Removal with Aqueous Chromic Acid-Phosphoric Acid Solution>

The removal of the barrier layer is preferably conducted by using an aqueous solution of phosphoric acid and chromic acid.

More specifically, a mixture of phosphoric acid, anhydrous chromic acid, and water is preferably used in the formulation as shown in Table 8 below.

TABLE 8

| 85% Phosphoric | Anhydrous | | | Typical |
|---|---|---|---|---|
| acid | chromic acid | Water | Temp. | immersion time |
| 100 to 140 g | 20 to 40 g | 1500 g | 50° C. | 0.1 μm/min |

The removal of the barrier layer may also be carried out by the method described in “Abstract of 108th Lecture Meeting” (18-B2, pages 76 to 77) published by The Surface Finishing Society of Japan.

The arithmetical mean roughness which is obtained from the values found in the directions parallel and perpendicular to the rolling direction is as set forth in Table 9 below after the polishing processes as above. (The roughness is commonly referred to as “centerline average roughness Rₐ”).

TABLE 9

| Polishing process | Rₐ [μm] |
|---|---|
| Mechanical polishing | 0.1 to 10 |
| Chemical polishing | 0.2 to 0.5 |
| Electrolytic polishing | 0.1 to 0.5 |
| Electrolytic-abrasive | 0.01 to 0.5 |
| polishing | |
| CMP method | <0.05 |
| Barrier layer removing method | <0.05 |

<Other Surface Treatments>

In the production method according to aspect (II) of the present invention, the aluminum substrate which has been subjected to the mechanical polishing or the auxiliary chemical polishing and/or electrolytic polishing is subjected to anodizing treatment.

<Recess Formation>

A method of subjecting an aluminum surface of a member to anodizing treatment preferably includes a process of forming recesses serving as starting points for micropore formation before an anodizing treatment for forming micropores (this treatment being hereinafter also referred to as “main anodizing treatment”). Such formation of recesses facilitates control of the arrangement of micropores and variation in pore diameter within a desired range as will be described later.

The method used for forming the recesses is not particularly limited. Examples thereof include a self-ordering method utilizing self-ordering property of an anodized layer, a physical method, a particle beam method, a block copolymer method, and a resist interference exposure method.

(1) Self-Ordering Method

Examples of the self-ordering method include that described as a preferred embodiment of anodizing treatment with regard to aspect (I) of the present invention.

More specifically, the self-ordering method involves using high purity aluminum; forming an anodized layer on the aluminum at a low speed and at a voltage adeoquate for the type of electrolyte solution used over a long period of time (of several hours to well over ten hours, for example); and subjecting the aluminum to layer removal treatment.

In this method, the pore diameter depends on the voltage, and thus a desired pore diameter can be obtained to some extent by controlling the voltage.

In each of the methods described in the documents as referred to before (Masuda, H. et al., Jpn. J. Appl. Phys., Vol. 37 (1998), pp. L1340-1342, Part 2, No. 11A, 1 November 1998 (FIG. 2); Masuda, H. et al., J. Electrochem. Soc., Vol. 144, No. 5, p. L128 (May 1997); Masuda, H. et al., Jpn. J. Appl. Phys., Vol. 35, Part 2, No. 1B, p. L126 (1996); and Masuda, H. et al., Appl. Phys. Lett., Vol. 71, No. 19, p. 2771 (Nov. 10, 1997)), the layer removal treatment for removing the anodized layer through dissolution is performed by using a mixed aqueous solution of chromic acid and phosphoric acid at about 50° C. and takes 12 or more hours. Treatment using the boiled aqueous solution destroys and disturbs the starting points for ordering, and therefore, the mixed aqueous solution is used without boiling.

The self-ordered anodized layer has higher ordering property in a portion closer to the aluminum member. The layer is removed once and a base portion of the anodized layer remaining on the aluminum surface is exposed to thereby obtain recesses which are regularly arranged. Accordingly, in the layer removal treatment, the aluminum is not dissolved, and only the anodized layer composed of aluminum oxide is dissolved.

As a result, in each of the methods described in the documents, variation (coefficient of variation) in pore diameter is 3% or less, although the magnitude of micropores is different in each case.

The self-ordering anodizing treatment used in aspect (II) of the present invention may be carried out, for example, by a method that involves application of an electric current through the aluminum substrate as the anode in a solution having an acid concentration of 1 to 10 wt %. Solutions that may be used in the anodizing treatment include any one or a combination of any two or more of sulfuric acid, phosphoric acid, chromic acid, oxalic acid, sulfamic acid, benzenesulfonic acid, and amidosulfonic acid.

The conditions for the self-ordering anodizing treatment cannot be determined unconditionally because the conditions vary in accordance with an electrolyte solution used. However, appropriate conditions generally include a concentration of the electrolyte solution of 1 to 10 wt %; a solution temperature of 0 to 20° C.; a current density of 0.1 to 10 A/dm²; a voltage of 10 to 200 V; and an electrolysis time of 2 to 20 hours.

Preferably, the self-ordered anodized layer has a thickness of 10 to 50 μm.

In aspect (II) of the present invention, the self-ordering anodizing treatment is carried out for a period of preferably 1 to 16 hours, more preferably 2 to 12 hours, and even more preferably 2 to 7 hours.

The layer removal treatment is carried out for a period of preferably 0.5 to 10 hours, more preferably 2 to 10 hours, and even more preferably 4 to 10 hours.

The self-ordering anodizing treatment and the layer removal treatment are each conducted for a shorter period of time than those conducted in the known methods. In consequence, the regularity of the micropore arrangement deteriorates slightly and the variation in pore diameter increases relatively to a coefficient of variation within a range of 5 to 50%.

When the anodized layer is formed and then dissolved for its removal through a self-ordering method as described above, and the main anodizing treatment described later is conducted under the same conditions, substantially straight micropores are formed substantially perpendicularly to the surface of the layer.

(2) Physical Method

An example of the physical method is a method employing press patterning. A specific example is a method in which a substrate having on the surface a plurality of protrusions is pressed against the aluminum surface to form recesses therein. For instance, the method described in JP 10-121292 A can be used.

Another example is a method in which polystyrene spheres are densely arranged on the aluminum surface, SiO₂ is vapor-deposited onto the spheres and the aluminum surface, then the polystyrene spheres are removed and the substrate is etched using the vapor-deposited Sio₂ as the mask, thereby forming recesses.

(3) Particle Beam Method

The particle beam method is a method in which recesses are formed by irradiating the aluminum surface with a particle beam. This method has the advantage in that the positions of the recesses can be freely controlled.

Examples of the particle beam include a charged particle beam, a focused ion beam (FIB), and an electron beam.

The particle beam method can disturb the regularity of the positions of the recesses by using random numbers for determination of the positions of the recesses. Accordingly, regularity of the arrangement of micropores formed by the subsequent main anodizing treatment is disturbed, to thereby readily realize desired variation in the pore diameter.

The positions of the recesses can be set as desired by using the following equation.
(Coordinates of desired position)=(Coordinates of perfectly ordered position)±(Coordinates of perfectly ordered position)×(Coefficient of variation)×(Random number)

When sealing treatment is conducted by an electrodeposition method, the coefficient of variation in pore diameter is preferably 0.05 to 0.5, more preferably 0.07 to 0.3, and even more preferably 0.1 to 0.2.

When the sealing treatment is conducted by a method using metal colloidal particles, the coefficient of variation in pore diameter is determined in accordance with the particle size distribution of the metal colloidal particles used.

An example of the particle beam method that can be used is the method described in JP 2001-105400 A.

(4) Block Copolymer Method

The block copolymer method is a method involving formation of a block copolymer layer on the aluminum surface, formation of a sea-island structure in the block copolymer layer by thermal annealing, and removal of the island portions to form recesses.

An example of the block copolymer method that can be used is the method described in JP 2003-129288 A.

(5) Resist Interference Exposure Method

The resist interference exposure method is a method involving provision of a resist on an aluminum surface, as well as exposure and development of the resist so as to form therein recesses penetrating to the aluminum surface.

An example of the resist interference exposure method that can be used is the method described in JP 2000-315785 A.

Of the various methods of forming recesses as described above, the self-ordering method, FIB method, and resist interference exposure method are desirable because they make it possible to uniformly form recesses over a large surface area of about 10 cm square or more.

From the standpoint of production costs, the self-ordering method is especially preferred. The FIB method is also preferable because it enables the arrangement of micropores to be controlled at will.

The recesses formed have a depth of preferably at least about 10 nm and a width which is preferably not greater than the desired pore diameter.

<Main Anodizing Treatment>

An anodized layer is formed on the aluminum surface by the main anodizing treatment preferably after recesses are formed in the aluminum surface as described above.

The main anodizing treatment may be carried out by any method known in the art, although use of the conditions identical to those employed for the self ordering method is preferred. The electrolysis voltage is preferably 10 to 240 V, and more preferably 10 to 60 V.

It is also preferable that the main anodizing treatment is conducted by repeating on-off control of electric current while keeping a DC voltage constant or, alternatively, while intermittently changing a DC voltage. With such a method being used, fine micropores are formed on the anodized layer and uniformity is improved particularly upon sealing treatment through electrodeposition.

In the method involving intermittent change of the voltage as above, the voltage is preferably reduced sequentially. In this way, the resistance of the anodized layer can be reduced, and the uniformity is achieved in the subsequent electrodeposition.

Once optimal conditions are substantially determined, the electrolysis may be conducted at a constant voltage, and when 0.3 M solution of sulfuric acid is used for the electrolyte solution, the electrolysis is preferably conducted at a constant voltage of 25 V, and when 0.5 M solution of oxalic acid is used for the electrolyte solution, the electrolysis is preferably conducted at a constant voltage of 40 V. When the electrolysis voltage is higher than the preferred voltage by about 1 V or more, the electric current will be concentrated on some parts of aluminum surface (phenomenon so called “burning”), rendering uniform electrolysis impossible. When the electrolysis voltage is lower than the preferred voltage by about 1 V or more, regularity will lack in some parts of the aluminum surface. Accordingly, it is preferable that the electrolysis voltage is higher than 24 V but lower than 26 V in the former case as above, and higher than 39 V but lower than 41 V in the latter.

When the main anodizing treatment is carried out at a low temperature, micropores are regularly arranged and the pore diameter is uniform.

In aspect (II) of the present invention, the main anodizing treatment may be carried out at a relatively high temperature to disturb the micropore arrangement and facilitate control of the variation in pore diameter to a specified range. The variation in pore diameter can also be controlled by adjusting the treatment time.

The anodized layer preferably has a thickness of 0.5 to 10 times, more preferably 1 to 8 times, and most preferably 1 to 5 times the pore diameter to facilitate the sealing.

The average pore diameter is preferably 10 nm or more if electrodeposition treatment is conducted later as the sealing treatment.

Accordingly, a preferable example of the anodized layer has a thickness of 0.1 to 1 μm and an average pore diameter of micropores of 0.008 to 0.2 μm (8 to 200 nm). The average pore diameter is preferably 8 to 200 nm, more preferably 8 to 100 nm, and still more preferably 8 to 65 nm.

The anodized layer has an average pore interval of preferably 23 to 600 nm, more preferably 24 to 500 nm, and still more preferably 63 to 500 nm.

The anodized layer has an average pore density of preferably 50 to 1,500 pores/μm², more preferably 5 to 800 pores/μm², and most preferably 200 to 800 pores/μm².

The micropores preferably account for an area ratio of 20 to 50%. The area ratio accounted for by the micropores is the ratio of the total area of openings of micropores to the area of the aluminum surface. Upon calculation of the area ratio accounted for by the micropores, the micropores used in the calculation include both the micropores that have been sealed with a metal and the non-sealed micropores. To be specific, the area ratio accounted for by the micropores is determined by measuring a surface porosity before the sealing treatment.

In an embodiment of the production method according to aspect (II) of the present invention, the aluminum substrate subjected to the mechanical polishing or the auxiliary chemical polishing and/or electrolytic polishing is subjected to the main anodizing treatment under the following exemplary conditions.

1) Anodizing treatment is conducted by using aqueous solution of sulfuric acid at a temperature in the range of 12 to 17° C. and a concentration in the range of 0.1 to 0.2 mol/L for the electrolyte solution, and at a voltage in the range of 23 to 26 V for a treatment time in the range of 0.5 to 12 hours to form micropores having an average pore diameter of 28 to 36 nm and an average pore interval of 40 to 80 nm.

2) Anodizing treatment is conducted by using aqueous solution of oxalic acid at a temperature in the range of 12 to 17° C. and a concentration in the range of 0.4 to 0.6 mol/L for the electrolyte solution, and at a voltage in the range of 38 to 42 V for a treatment time in the range of 0.5 to 7 hours to form micropores having an average pore diameter of 20 to 45 nm and an average pore interval of 80 to 120 nm.

3) Anodizing treatment is conducted by using an acidic aqueous solution at a temperature in the range of 0 to 25° C. and a concentration in the range of 0.01 to 2 mol/L for the electrolyte solution, and at a voltage in the range of 23 to 400 V for a treatment time in the range of 0.5 to 12 hours.

<Evaluation of Micropores>

Average pore diameter and average pore interval of the micropores were measured by image analysis of the SEM photograph of the aluminum surface.

(Measurement of Average Pore Diameter and Average Pore Interval)

Distance between the centers of adjacent pores was measured at 30 points in the SEM photograph (gradient, 0 degrees) taken with a field emission type scanning electron microscope (FE-SEM) under a 1× to 150,000× magnification adjusted depending on the pore diameter, and the average of 30 measurement values was found as the average pore interval.

Such measurement is conducted under an adequate magnification allowing preferably 60 to 250 pores, and more preferably 80 to 200 pores to be seen in one coverage.

Average pore diameter was determined by tracing contours of about 100 pores on a transparent OHP sheet, and using an image analysis package (Image Factory (product name) manufactured by Asahi HiTech Co., Ltd.) to perform approximation to an equivalent circle diameter so as to regard the found value as the average pore diameter. The image analysis package is not limited to the one as mentioned above, and any package having equivalent functions may be used. However, in order to strictly exclude arbitrariness associated with the setting of the threshold during the binarization, the image analysis is preferably conducted for the shape that has been traced onto a transparent sheet such as OHP sheet.

<Pore Widening Treatment>

As in the case of aspect (I) of the present invention, the pore widening treatment is a treatment wherein the aluminum member after the main anodizing treatment is immersed in an aqueous acid solution or aqueous alkali solution to dissolve the anodized layer and increase pore diameter of the micropores.

Such treatment facilitates control of the regularity in the arrangement of the micropores and variation in the pore diameter of the micropores. Dissolution of the barrier layer at the bottom of the micropores in the anodized layer enables selective electrodeposition in the interior of the micropores and slight increase in the variation in the pore diameter.

<Other Treatments>

As in the case of aspect (I) of the present invention, other treatments may also be conducted as required.

<Production of Structures by Using a Structure as a Mold>

The nanostructure produced by the production method according to aspect (II) of the present invention may be used as a mold for producing further nanostructures.

The structure according to aspect (II) of the present invention is used as a mold. The structure as a mold is pressed against an aluminum surface at a pressure of approximately 2.5 t/m² to form regularly arranged recesses therein, and the resulting aluminum surface is used as such or subjected to anodizing treatment so as to produce a nanostructure.

The aluminum surface is not particularly limited. However, preferred is an aluminum surface prepared by using the aluminum substrate with an aluminum purity of 99.9% or higher used in the production method according to aspect (II) of the present invention, and at least mechanically polishing its surface to reduce the arithmetical mean roughness Rₐ to 0.1 μm or lower and the glossiness to 60% or higher.

<Sealing Treatment>

The structure according to aspect (II) of the present invention may be made into an electromagnetic device by a sealing treatment in which the micropores of the anodized layer are filled with a metal material, a magnetic material, or the like.

The metals which may be used in the sealing treatment include those used in aspect (I) of the present invention.

Exemplary magnetic materials which may be used in the sealing treatment include iron, nickel, cobalt, as well as alloys and oxides thereof.

The method used in the sealing treatment is not particularly limited, and a method known in the art may be used as in the case of aspect (I). The sealing treatment is described in the following by referring to the treatment using a metal material.

Exemplary preferable methods include electrodeposition and the method wherein a dispersion of metal colloidal particles is applied to an aluminum member having the anodized layer, and then caused to dry. The metal is preferably in the form of metal particles or aggregates of such metal particles.

The electrodeposition may be carried out by the same method as the one described above for aspect (I).

When the sealing treatment is conducted by electrodeposition, the metal particles are deposited at varying distance due to the variation in the pore diameter. As a consequence, it is relatively easy to realize the situation in which some of the metal particles are located in close proximity with each other. As long as some metal particles are located in close proximity with each other, surface-enhanced resonance Raman scattering can be utilized even if other particles were located remote from each other or in contact with each other.

In contrast, when the conventional anodized layer having micropores of uniform pore diameter is subjected to a sealing treatment by electrodeposition, the resulting metal particles are located at a uniform interval, and it is difficult to adjust such interval to the range appropriate for the surface-enhanced resonance Raman scattering. When the particle interval is out of an appropriate range, all particles are located either remote from each other or in contact with each other, and use of the surface-enhanced resonance Raman scattering is not available.

After application of the dispersion, the surface is cleaned with a solvent such as water as appropriate. As a result, only particles filled into the micropores remain at the anodized layer, with the particles not filled into the micropores being removed.

The amount of metal remaining attached after the sealing treatment is preferably in the range of 100 to 500 mg/m² as in the case of aspect (I).

The surface after the sealing treatment preferably has a surface porosity of 20% or less as in the case of aspect (I). The surface porosity after the sealing treatment refers to the ratio of the total area of the openings of unsealed micropores to the area of the aluminum surface, and the surface porosity within the above specified range provides further enhanced localized plasmon resonance.

The metal colloidal particles used in the dispersion usually have a variation in the particle size distribution of approximately 10 to 20% in terms of coefficient of variation. In the present invention, colloidal particles having a variation in the particle size distribution can be efficiently used in the sealing treatment by adequately limiting the pore diameter variation to a particular range.

At a pore diameter of 50 nm or more, the use of metal colloidal particles is preferred. At a pore diameter of less than 50 nm, the use of an electrodeposition process is preferred. Suitable use can also be made of a combination of both.

<Electromagnetic Device>

The electromagnetic device of the present invention produced as described above has its micropores filled with a metal material or a magnetic material, and such metal or magnetic material is present in the form of particles on the surface of the anodized layer.

In general, as in the case of aspect (I), the distance between the particles of metal and so forth is preferably small for increasing a Raman enhancing effect, but the optimal distance depends on the size and shape of the particles. Further, depending on the molecular weight of the substance or the viscosity of the liquid used as a sample for Raman spectroscopic analysis, a problem may be caused in that the substance or the liquid does not sufficiently penetrate through the gap between the particles.

<Raman Enhancing Effect by Localized Plasmon Resonance>

The structure according to aspect (II) of the present invention that has metal particles filled into its micropores can generate localized plasmon resonance which has an intensity larger than the conventional structures, and use of such structure in the Raman spectroscopic analysis facilitates further increased Raman enhancing effect. Accordingly, the sample holder for Raman spectroscopic analysis produced by using the structure according to aspect (II) of the present invention is quite useful.

The usage of the sample holder for Raman spectroscopic analysis of the present invention is the same as that of a conventional sample holder for Raman spectroscopic analysis. To be specific, properties of a substance in the vicinity of the metal attached to the sample holder are detected by irradiating the sample holder for Raman spectroscopic analysis of the present invention with a light beam, and measuring the Raman scattering intensity of the reflected light or transmitted light.

The nanostructure according to aspect (II) of the present invention can be used by itself as a functional material, and also, as a matrix or mold for a new nanostructure, for example, by filling the micropores in the nanostructure of the present invention with a metal, a semiconductor, or other functional material to develop a new electronic device.

The nanostructure according to aspect (II) of the present invention may also be used in a remarkably extended variety of applications such as quantum wire, molecule sensor, coloring, solar cell, gas sensor, and precision filter; as well as such electoromagnetic devices as magnetic recording medium, optical devices including light emitting EL device, electrochromic device and photonic band, and electron releasing device.

### EXAMPLES

Next, the present invention is described in more detail with reference to Examples relating to aspect (I) of the present invention. However, aspect (I) of the present invention is not limited to such Examples.

1. Production of Structure

### Examples 1 to 10

An aluminum substrate was subjected to a mirror finishing treatment, a self-ordering anodizing treatment, and a reverse electrolysis in this order to obtain a structure composed of an anodized layer, and the substrate. The resulting aluminum substrate was subjected to a main anodizing treatment, a pore widening treatment, a sealing treatment, a surface treatment, and an electrodeposition in this order to thereby obtain a structure composed of the aluminum substrate having micropores which are sealed with a metal.

Each treatment will be described below in more detail.

(1) Substrate

The following substrate was used for the production of the structures.

Substrate: a high purity aluminum available from Wako Pure Chemical Industries, Ltd. having an aluminum purity of 99.99 wt % and a thickness of 0.4 mm.

(2) Mirror Finishing Treatment

The substrate was subjected to the following mirror finishing treatment.

<Mirror Finishing Treatment>

The mirror finishing treatment was conducted through polishing using a polishing cloth, buff polishing, namely buffing, and electrolytic polishing in this order. After the buffing, the substrate was washed with water.

The polishing using a polishing cloth was conducted by using a polishing machine (Struers Abramin manufactured by Marumoto Kogyo K.K.) and water resistant polishing cloths (commercially available products) with grit numbers #200, #500, #800, #1000 and #1500 while the polishing cloths were changed in order of grit number, from the lowest toward a higher.

The buffing was conducted by using slurry abrasives (FM No. 3 (mean particle size of 1 μm) and FM No. 4 (mean particle size of 0.3 μm), both manufactured by Fujimi Incorporated).

The electrolytic polishing was conducted by using an electrolyte solution having the following composition (at 70° C.), and with a constant current of 130 mA/cm² for 2 minutes, whereupon the substrate served as an anode, and a carbon electrode as a cathode. GP0110-30R (manufactured by Takasago, Ltd.) was used as a power source.

<Composition of electrolyte solution>

| | |
|---|---|
| 85 wt % phosphoric acid (manufacture by Wako | 660 mL |
| Pure Chemical Industries, Ltd.) | |
| Pure water | 160 mL |
| Sulfuric acid | 150 mL |
| Ethylene glycol | 30 mL |

(3) Self Ordering Anodizing Treatment (Recess Formation)

The mirror-finished surface of the substrate was subjected to the self ordering anodizing treatment below so as to form recesses therein. The recesses thus formed were the starting points for micropore formation in the main anodizing treatment described later.

<Self Ordering Anodizing Treatment>

An aqueous solution of sulfuric acid having a concentration of 0.3 mol/L and a temperature of 16° C. was prepared by using sulfuric acid available from Kanto Chemical Co., Inc. The substrate was immersed in this aqueous solution of sulfuric acid, and subjected to self ordering anodizing treatment under the conditions of a voltage of 25 V and a current density of 0.8 A/dm² (in stable state) for 7 hours to thereby form an anodized layer having a thickness of 90 μm on the substrate.

For the self-ordering anodizing treatment, NeoCool BD36 (manufactured by Yamato Scientific Co., Ltd.) was used as a cooler, and a pair stirrer PS-100 (manufactured by Tokyo Rikakikai Co., Ltd.) was used as a stirring apparatus under heating. GP0650-2R (manufactured by Takasago, Ltd.) was used as a power source. The surface of the substrate not facing the electrode was preliminarily covered by attaching a PET tape (Dampron manufactured by Nitto Denko Corporation) to avoid the anodization.

<Layer Thickness Measurement>

The substrate having the anodized layer formed thereon was bent, and the side (the broken surface) at the crack of the layer was observed by using an ultra-high resolution SEM (Hitachi S-900 manufactured by Hitachi, Ltd.) at an acceleration voltage of 20 V and under a magnification of 200 times to measure the layer thickness. The measurement was conducted by randomly selecting 10 measuring points at a time, and the layer thickness was found as the average of the thickness values measured at the 10 points. The thickness values obtained at the 10 points were each within ±10% of the average.

(4) Reverse Electrolysis

The aluminum substrates each having the anodized layer formed thereon were subjected to reverse electrolysis by using the aqueous acid solutions A1 to A5 and B1 to B3 having the properties shown in Table 10 under the conditions shown in Table 11 to strip the anodized layers off the substrates. The aqueous acid solutions A1 to A5 were each prepared by adding aluminum sulfate in addition to the sulfuric acid so that the aluminum concentration would be 0.2 g/L. The electrolysis was terminated immediately after the current value had reached its minimum value by monitoring the current value with an ammeter.

TABLE 10

| Aqueous | | | | Electric |
|---|---|---|---|---|
| acid | | Concentration | | conductivity |
| solution | Main ingredient | (g/L) | pH | (mS/cm) |
| A1 | Sulfuric acid | 0.1 | 3.0 | 10 |
| A2 | Sulfuric acid | 1.0 | 2.0 | 16 |
| A3 | Sulfuric acid | 6.0 | 1.7 | 25 |
| A4 | Sulfuric acid | 10.0 | 1.0 | 43 |
| A5 | Sulfuric acid | 100.0 | −0.2 | 480 |
| B1 | Aluminum sulfate | 0.04 | 3.8 | 0.5 |
| B2 | Aluminum sulfate | 0.53 | 3.3 | 2.5 |
| B3 | Aluminum sulfate | 12.60 | 2.3 | 29 |

TABLE 11

| | Aqueous acid | Voltage | Treatment | Chemical |
|---|---|---|---|---|
| Example | solution | (V) | time (sec.) | treatment |
| 1 | A1 | 25 | 50 | No |
| 2 | A2 | 25 | 31 | No |
| 3 | A3 | 25 | 20 | No |
| 4 | A4 | 25 | 12 | No |
| 5 | A4 | 25 | 12 | Yes |
| 6 | A5 | 25 | 1 | No |
| 7 | A5 | 25 | 1 | Yes |
| 8 | B1 | 25 | 480 | No |
| 9 | B2 | 25 | 300 | No |
| 10 | B3 | 25 | 20 | No |

(5) Chemical Treatment

In Examples 5 and 7, the aluminum substrate after the stripping was further subjected to a chemical treatment in which the aluminum substrate was immersed in a mixed aqueous solution of chromic acid and phosphoric acid (composition: 30 g of anhydrous chromic acid, 100 g of 85 wt % phosphoric acid, and 1500 g of water; temperature, 50° C.) for 5 minutes.

(6) Main Anodizing Treatment

The aluminum substrates that had been produced by stripping the anodized layer by reverse electrolysis in Examples 1 and 8 were subjected to the main anodizing treatment. The main anodizing treatment was conducted by immersing the aluminum substrate in the aqueous solution of sulfuric acid at a concentration of 0.3 mol/L and at 16° C., which was the same as the solution used in the self ordering anodizing treatment, and at a voltage of 25 V and a current density of 0.8 A/dm² (in stable state) for 60 seconds to thereby form an anodized layer having a thickness of 100 nm on the substrate.

(7) Pore Widening Treatment

The aluminum substrate that had been subjected to the main anodizing treatment was subjected to the pore widening treatment in order to improve uniformity of the sealing treatment as described below. The treatment was conducted by immersing the aluminum substrate in an aqueous solution of phosphoric acid at a concentration of 50 g/L and at a temperature of 30° C., for 20 minutes in the case of the aluminum substrate obtained in Example 1, and 6 minutes in the case of the aluminum substrate obtained in Example 8.

(8) Sealing Treatment

The aluminum substrate that had been subjected to the pore widening treatment was subjected to the sealing treatment by electrodeposition. The electrodeposition was conducted for 5 minutes by using an aqueous solution containing HAuCl₄.4H₂O at a concentration of 1 g/L and H₂SO₄ at a concentration of 7 g/L at 30° C. for the plating solution and a high purity platinum plate for the counter electrode, and applying an AC voltage of 11 V adjusted with a slidax.

### Comparative Example 1

The procedure of Example 1 was repeated except that the reverse electrolysis was replaced with the layer removal treatment by immersion of the aluminum substrate in a mixed aqueous solution of chromic acid and phosphoric acid (composition: 30 g of anhydrous chromic acid, 100 g of 85 wt % phosphoric acid, and 1500 g of water; temperature, 50° C.) for 12 hours.

As a result of such layer removal treatment, the anodized layer dissolved to leave the aluminum substrate. Accordingly, no anodized layer as a structure was obtained.

### Comparative Example 2

The procedure of Comparative Example 1 was repeated except that, in the layer removal treatment, the substrate was immersed in the mixed aqueous solution of chromic acid and phosphoric acid for 480 seconds.

The aluminum substrate obtained by such layer removal treatment had residue of the anodized layer over the entire aluminum substrate, and no anodized layer as a structure was obtained.

### Examples 11 and 12

In these Examples, the aluminum substrates used were substrate 7 and substrate 10 used in the Examples corresponding to aspect (II) of the present invention as described later. The substrate was subjected sequentially to the self-ordering anodizing treatment and the reverse electrolysis as described below to obtain a structure composed of an anodized layer and the substrate as left. The thus obtained aluminum substrate was further subjected to the main anodizing treatment, the pore widening treatment, the sealing treatment, the surface treatment, and the electrodeposition treatment in this order to produce a structure composed of the aluminum substrate having the micropores sealed with a metal. The substrate used in Example 11 was substrate 7, and the substrate used in Example 12 was substrate 10.

The treatments are described in detail.

(1) Self Ordering Anodizing Treatment (Recess Formation)

Recesses serving as starting points for micropore formation in the main anodizing treatment described later were formed in the surface of the substrate by the self ordering anodizing treatment as below.

<Self Ordering Anodizing Treatment>

In each of Examples 11 and 12, the substrate was subjected to the same self ordering anodizing treatment as Examples 1 to 10 except that the electrolyte solution contained aluminum sulfate in addition to sulfuric acid so that the aluminum concentration would be 8 g/L and a current density of 0.6 A/dm² was used, to thereby form an anodized layer with a thickness of 70 μm on the substrate.

<Layer Thickness Measurement>

The layer thickness was measured by the same procedure as Examples 1 to 10. The thickness values obtained at the 10 points were each within ±10% of the average.

(2) Reverse Electrolysis

The aluminum substrate having the anodized layer formed thereon was subjected to the reverse electrolysis by using the aqueous acid solution B1 having the properties shown in Table 10 under the conditions shown in Table 11 to strip the anodized layer off the substrate.

(3) Main Anodizing Treatment

The aluminum substrate after stripping was subjected to the main anodizing treatment under the conditions shown in Table 12 below to form an anodized layer having a thickness of 200 μm on the substrate.

TABLE 12

| | | Conditions | | | | | | |
|---|---|---|---|---|---|---|---|---|
| | | for main | | | | | Current | Treatment |
| | | anodizing | Electrolyte | Concentration | Temp. | Voltage | density | time |
| | Substrate | treatment | solution | (mol/L) | (° C.) | (V) | (A/dm²) | (min.) |
| Ex. 11 | 7 | A | Sulfuric | 0.3 | 16 | 25 | 0.8 | 2 |
| | | | acid | | | | | |
| Ex. 12 | 8 | A | Sulfuric | 0.3 | 16 | 25 | 0.8 | 2 |
| | | | acid | | | | | |

(4) Pore Widening Treatment

The aluminum substrate that had been subjected to the main anodizing treatment was subjected to the pore widening treatment in order to improve uniformity of the sealing treatment as described below. The treatment was conducted under the same conditions as those of Example 8 except that the immersion time was 15 minutes.

(5) Sealing Treatment

The aluminum substrate that had been subjected to the pore widening treatment was subjected to the sealing treatment under the same conditions as those of Example 8.

2. Evaluation of the Stripping

The surface of the aluminum substrate after stripping the anodized layer off the aluminum substrate by the reverse electrolysis was evaluated for the substrates obtained in the Examples. The evaluation was conducted by visually inspecting the stripped surface of the aluminum substrate after the reverse electrolysis for preence of the anodized layer remaining on the surface (residual layer) and for corrosion. In the case of Examples 5 and 7, the surface of the aluminum substrate after the chemical treatment was evaluated.

The results are shown in Table 13. In Table 13, regarding the item of “Presence of residual layer on stripped surface”, the aluminum substrate whose surface was occupied by the residual layer at a proportion of 0% or less than 3% based on the area was evaluated as “Good”, and the aluminum substrate in which the proportion was 3% or more but less than 10% was evaluated as “Fair”. Regarding the item of “Corrosion of stripped surface”, the aluminum substrate whose surface was corroded at a proportion of 0% or less than 3% based on the area was evaluated as “Good”, and the aluminum substrate in which the proportion was 3% or more but less than 10% was evaluated as “Fair”.

As evident from Table 13, the aluminum substrate produced by the structure production method according to aspect (I) of the present invention scarcely had the residual layer on its stripped surface. Even if the residual layer was more or less present (Examples 4 and 6), such a layer could be reduced by conducting chemical treatment after the reverse electrolysis (Examples 5 and 7).

TABLE 13

| | Presence of residual layer | Corrosion of stripped |
|---|---|---|
| Example | on stripped surface | surface |
| 1 | Good | Good |
| 2 | Good | Good |
| 3 | Good | Good |
| 4 | Fair | Fair |
| 5 | Good | Fair |
| 6 | Fair | Fair |
| 7 | Good | Fair |
| 8 | Good | Good |
| 9 | Good | Good |
| 10 | Good | Good |
| 11 | Good | Good |
| 12 | Good | Good |

3. Evaluation of the structure composed of the anodized layer

Aqueous solution of phosphoric acid at a concentration of 50 g/L (temperature, 25° C.) was so dropped onto the stripped surface of the anodized layers produced in Examples 1, 6, 11 and 12 by the reverse electrolysis as to wet the entire surface, and after 20 minutes, the anodized layers were washed with water and dried. The anodized layers had a thickness of 70 μm each.

Next, the stripped surface of each anodized layer was observed with SEM. It was then found the anodized layer including the barrier layer had partly been dissolved away by the aqueous solution of phosphoric acid, and the micropores were found exposed at the stripped surface. More specifically, the bottom of the micropores had disappeared by the dissolution to leave the micropores extending through the anodized layer.

The stripped surface with the exposed micropores was photographed with FE-SEM (S-900 manufactured by Hitachi, Ltd.) at an acceleration voltage of 12 V under a magnification of 100,000 times. The SEM photograph thus taken was read with a scanner, and thresholding was performed using an image processing package (Image Factory manufactured by Asahi HiTech Co., Ltd.). Shape of the micropores was then approximated to the equivalent circles, and average pore diameter and standard deviation of the pore diameter were calculated from the distribution of the circle diameter. Coefficient of variation in the pore diameter was then calculated by diving the standard deviation of the pore diameter by the average pore diameter. Average distance between adjacent pore centers (pore interval) was also found by actually measuring the distance between adjacent pore centers for 100 micropores and calculating the average of the measured values.

The structure composed of the anodized layer had an average pore diameter of 30 nm in all of Examples 1, 8, 11 and 12; a coefficient of variation in the pore diameter of 3% in all of Examples 1, 8, 11 and 12; and a pore interval of 63 nm in both of Examples 1 and 8.

4. Evaluation of the Structure Composed of the Aluminum Substrate

(1) Properties of the Structure

The aluminum substrates after the pore widening treatment of Examples 1, 8, 11 and 12 and the aluminum substrates of Comparative Examples 1 and 2 were measured for their average pore diameter, coefficient of variation in the pore diameter, and pore interval in such a manner as described above.

The structure composed of the aluminum substrate after the pore widening treatment had an average pore diameter of 30 nm in both of Examples 1 and 8; a coefficient of variation in the pore diameter of 3% in all of Examples 1, 8, 11 and 12; and a pore interval of 63 nm in all of Examples 1, 8, 11 and 12. On the other hand, the structure composed of the aluminum substrate produced in Comparative Example 1 had an average pore diameter of 30 nm, a coefficient of variation in the pore diameter of 3%, and a pore interval of 63 nm, and the structure composed of the aluminum substrate produced in Comparative Example 2 had an average pore diameter of 40 nm, a coefficient of variation in the pore diameter of 15%, and a pore interval of 63 nm.

(2) Raman Enhancing Effect

3×10⁻⁷ mol/L aqueous solution of rhodamine 6G (manufactured by Kanto Chemical Co., Inc.), and 0.1 mol/L aqueous solution of NaCl (manufactured by Kanto Chemical Co., Inc.) were applied to the surface of the structures composed of the aluminum substrates after the sealing treatment of Examples 1, 8, 11 and 12, and Raman scattering intensity at 1660 cm⁻¹ was measured by using a Raman spectroscopic analyzer (T64000 manufactured by HORIBA, Ltd.) at an excitation wavelength of 488 nm and with a Raman shift to be measured of 800 to 1800 cm⁻¹.

The value of the Raman scattering intensity measured was divided by the value of the Raman scattering intensity at 1660 cm⁻¹ measured for an ordinary slide glass with the maximum laser output to calculate enhancement factor, and to thereby evaluate the Raman enhancing effect. When the sensitivity was excessively high, the enhancement factor was calculated by reducing the laser output and diluting the aqueous solution of rhodamine 6G with water.

It was then found that the structure composed of the aluminum substrate after the sealing treatment had an enhancement factor of the Raman enhancing effect which is 10⁴ or more in any of Examples 1, 8, 11 and 12.

Next, the present invention is described in further detail by referring to Examples corresponding to aspect (II) of the present invention. However, aspect (II) of the present invention is not limited to such Examples.

1. Polishing of the Aluminum Substrate

The aluminum plate used was a custom made 5N aluminum plate manufactured by Nippon Light Metal Co., Ltd. having a size of 5 cm×5 cm. The results of the analysis are shown in Table 14 in wt %. The aluminum plate was polished by the mechanical polishing, the chemical polishing, the electrolytic polishing, the CMP method, and the barrier layer removing method as described below. Table 16 shows the procedure used for the polishing, together with blister density, Rₐ, and average glossiness measured for the resulting aluminum surface. “-” means that the relevant treatment was not conducted.

TABLE 14

Element

| | Fe | Si | Cu | Al |
|---|---|---|---|---|
| Content | less | less | less | 99.999% or |
| | than | than | than | higher |
| | 0.0002% | 0.0002% | 0.0002% | |

A1) Mechanical Polishing

A sample (5 cm×5 cm) was adhered to a mirror finished metal block with a double sided adhesive tape (removable tape 9455 manufactured by Sumitomo 3M Limited). The sample was polished until no surface irregularities were detected by visual inspection by using a polishing machine (LaboPol-5 manufactured by Marumoto Struers) and polishing papers (water-resistant polishing papers manufactured by Marumoto Struers) with grit numbers #80, #240, #500, #1000, #1200 and #1500, and changing the polishing papers in order of grit number, from the lowest toward a higher.

A2) Mechanical Polishing

A sample (5 cm×5 cm) was adhered to a mirror finished metal block with a double sided adhesive tape (removable tape 9455 manufactured by Sumitomo 3M Limited). The sample was polished until no surface irregularities were detected by visual inspection by using a polishing machine (LaboPol-5 manufactured by Marumoto Struers) and changing the abrasives and polishing cloths as described below.

Abrasive: Diamond abrasives (DP-Spray P series manufactured by Marumoto Struers)

Buff: Polishing cloths No. 773 (particle size, 10 μm or more) and No. 751 (particle size, less than 10 μm) manufactured by Marumoto Struers

To the buffs, the diamond abrasives SPRIR (particle size, 45 μm), SPRAM (particle size, 25 μm), SPRUF (particle size, 15 μm), SPRAC (particle size, 9 μm), SPRIX (particle size, 6 μm), SPRRET (particle size, 3 μm), SPRON (particle size, 1 μm), and SPRYT (particle size, 0.25 μm) were applied in this order so as to use the buffs for mirror finishing. The buffs were changed with the replacement of the abrasives.

A3) Mechanical Polishing

A sample (5 cm×5 cm) was adhered to a mirror finished metal block with a double sided adhesive tape (removable tape 9455 manufactured by Sumitomo 3M Limited). The sample was polished until no surface irregularities were detected by visual inspection by using a polisher (8-inch Si wafer manufactured by Shin-Etsu Chemical Co., Ltd.) and polishing films (Imperial lapping film sheets, type PSA manufactured by Sumitomo 3M Limited) with grit numbers #320, #600, #1000, #1200, #2000, #4000, #6000, #8000, #10000 and #15000, and changing the polishing films in order of grit number, from the lowest toward a higher.

A4) Electrolytic Abrasive Polishing

A sample (5 cm×5 cm) was adhered to a mirror finished metal block with a double sided adhesive tape (removable tape 9455 manufactured by Sumitomo 3M Limited). The sample was polished by using a polishing machine (PIEP-10 manufactured by Corporate Sugiyama Shoji) at a main spindle rotation speed of 150 rpm, a main spindle oscillation frequency of 2 Hz, an X axis feed speed of 2 mm/sec, a pressing pressure of 50 g/cm², as well as an electrolysis power voltage of 1 V and electric current of 2 A (polishing area, 5 cm×5 cm).

Abrasive slurries each having a concentration of 20 vol % were prepared by adding alumina abrasives of #40, #80, #400, #1000 and #1500 in 0.1 mol/L aqueous solutions of sodium nitrate, respectively.

The sample was polished until no surface irregularities were detected by visual inspection by changing the alumina abrasive slurries in order of abrasive grit number, from #40 toward a higher. The sample was finished by polishing with colloidal silica PL-3 having 0.1 mol/L of sodium nitrate added thereto.

B) Chemical Polishing

Chemical polishing was conducted under conditions as shown in Table 15 below.

TABLE 15

| Phosphoric | Aluminum | Nitric | | | | Surface |
|---|---|---|---|---|---|---|
| acid | phosphate | acid | Water | Temp. | Time | quality |
| 76% | 5.5% | 3.3% | 15.2% | 100° C. | 120 sec. | Good |

C) Electrolytic Polishing

Electrolytic polishing was conducted under following conditions.

| | |
|---|---|
| 85 wt % phosphoric acid (manufactured by Wako Pure Chemical | 660 cc |
| Industries, Ltd.) | |
| Pure water | 160 cc |
| Sulfuric acid | 150 cc |
| Ethylene glycol | 30 cc |

Temperature: 70° C.

Anode: sample

Cathode: carbon

Electrolysis: a constant current of electrolysis at 130 mA/cm² for 2 minutes

Power source: GP0110-30R (manufactured by Takasago, Ltd.) D) Chemical mechanical polishing (CMP) method

The sample was polished on an ultraprecision polishing machine (MA-200D manufactured by Musasino Denshi Corporation) at a rotation speed of 50 rpm for 10 minutes using the following slurries, the coarser first. A 3 wt % aqueous solution of phosphoric acid was sprayed onto the sample as appropriate.

(1) Diamond slurry #2400000 having a particle size of 0.1 μm

(2) Aluminum oxide slurry having a particle size of 0.05 μm

E) Barrier Layer Removing Method

The sample was subjected to anodic electrolysis in a solution at 50° C. containing ammonium adipate at a concentration of 15 wt % until the voltage reached 100 V to form an anodized layer with no micropores which had a thickness of about 0.1 μm. The sample was then immersed in an aqueous solution of chromic acid (118 g of 85 wt % phosphoric acid, 30 g of anhydrous chromic acid, and 1500 g of pure water) at 50° C. for 1 minute to remove the barrier layer and smoothen the surface.

TABLE 16

| | | | | | | | | | Density | | |
|---|---|---|---|---|---|---|---|---|---|---|---|
| | | | | Electrolytic- | | | | Barrier | of | | |
| | Mechanical | | | abrasive | Chemical | Electrolytic | | layer | remaining | | Average |
| Substrate | polishing | | | polishing | polishing | polishing | CMP | removing | blisters | Rₐ | glossiness |
| No. | A1 | A2 | A3 | A4 | B | C | D | E | [/dm²] | [μm] | [%] |
| 1 | Yes | — | — | — | — | — | — | — | 0 | 0.1 | 75 |
| 2 | — | Yes | — | — | — | — | — | — | 0 | 0.1 | 75 |
| 3 | — | — | Yes | — | — | — | — | — | 0 | 0.1 | 85 |
| 4 | — | — | — | Yes | — | — | — | — | 0 | 0.1 | 85 |
| 5 | Yes | Yes | Yes | — | Yes | — | — | — | 0 | 0.08 | 80 |
| 6 | Yes | Yes | Yes | — | — | Yes | — | — | 0 | 0.06 | 80 |
| 7 | Yes | Yes | Yes | — | Yes | — | Yes | — | 0 | 0.01 | 90 |
| 8 | Yes | Yes | Yes | — | — | Yes | Yes | — | 0 | 0.01 | 90 |
| 9 | Yes | Yes | Yes | — | Yes | — | — | Yes | 0 | 0.03 | 85 |
| 10 | Yes | Yes | Yes | — | — | Yes | — | Yes | 0 | 0.03 | 85 |
| 11 | — | — | — | Yes | — | — | — | — | 0 | 0.06 | 80 |
| 12 | — | — | — | Yes | — | — | Yes | — | 0 | 0.01 | 90 |
| 13 | — | — | — | Yes | — | — | — | Yes | 0 | 0.03 | 85 |
| 21 | — | — | — | — | — | — | — | — | 150 | 0.2 | 60 |
| 22 | — | — | — | — | — | Yes | — | — | 150 | 0.1 | 75 |

2. Evaluation of the Polished Surface
<Evaluation of Surface Roughness>

The surface roughness Rₐ was first measured with a contact-probe profilometer, and when Rₐ was 0.1 μm or less, it was further measured with AFM. When Rₐ in Table 16 is more than 0.1 μm, the surface roughness was measured with a sapphire probe having a tip radius of 10 μm, and in other cases, the surface roughness was measured with AFM.

(1) Measurement of Rₐ with Profilometer

Rₐ was measured according to JIS-B601-1994.

Rₐ was determined by folding the roughness curve at the centerline and dividing the area between the roughness curve and the centerline by the length L. Rₐ is represented in micrometer Model: SURFCOM 575A manufactured by Tokyo Seimitsu Co., Ltd.

Measurement conditions: Cut off, 0.8 mm; gradient correction, FLAT-ML; sampling length, 2.5 mm; T-speed, 0.3 mm/s; polarity, positive

Probe: sapphire probe having a tip radius of 10 μm

(2) Measurement of Rₐ with AFM

When Rₐ was 0.1 μm or less, Rₐ was measured again with AFM (DFM cyclic contact mode).

Scanning area: 3000 nm

Scanning frequency: 0.5 Hz

Amplitude attenuation: −0.16

I gain: 0.0749; P gain: 0.0488

Q curve gain: 2.00

Vibrating voltage: 0.044 V

Resonance frequency : 318.5 kHz

Measurement frequency: 318.2 kHz

Vibration amplitude: 0.995 V

Q value: approx. 460

Measurement stylus: Si stylus having a tip diameter of 10 nm (cantilever SI DF40P manufactured by Seiko Instruments Inc.)

<Measurement of Glossiness>

The glossiness was evaluated by measuring specular reflectance under the following conditions in accordance with JIS Z 8741-1997 “Method 3, 60 degree specular glossiness”. The results are shown in Table 16.

Apparatus: Σ80 (VG-1D) manufactured by Nippon Denshoku Industries Co., Ltd

Measuring angle; 60 degrees

The measurement was conducted with the light path in both longitudinal and transverse directions parallel and perpendicular to the rolling direction, respectively, and the average was calculated.

### Examples 13 to 18 and Comparative Examples 3 to 5

Nanostructures were produced by using the substrates 7 and 10 and the substrate 22 for comparison purpose.

[Anodizing Treatment]

The sample was subjected to the following treatments after adhering a PET tape to the back side of the sample in order to prevent the back side (side not to be anodized) from being anodized.

<Self Ordering Treatment>

TABLE 17

| Conditions | | | | | | | |
|---|---|---|---|---|---|---|---|
| for | | | | | | | |
| self- | | | | | Current | Treatment | Layer |
| ordering | Electrolyte | Concentration | Temp. | Voltage | density | time | thickness |
| treatment | solution | [mol/L] | [° C.] | [V] | [A/dm²] | [hours] | [μm] |
| A | Sulfuric | 0.3 | 16 | 25 | 0.8 | 7 h | 70 |
| | acid | | | | | | |
| B | Oxalic acid | 0.5 | 16 | 40 | 0.4 | 5 h | 60 |
| C | Phosphoric | 0.2 | 0 | 195 | 0.4 | 1 h | 15 |
| | acid | | | | | | |

<Layer Removal Treatment>

Phosphoric acid, anhydrous chromic acid, and water were mixed in line with the following formulation.

TABLE 18

| 85% phosphoric | Anhydrous | | | Immersion |
|---|---|---|---|---|
| acid | chromic acid | Water | Temp. | time |
| 118 g | 30 g | 1500 g | 50° C. | 10 hours |

<Main Anodizing Treatment>

The main anodizing treatment was conducted under the conditions shown in Table 19. The surface properties were measured as described below. The results are shown in Table 19. The layers produced by using the main anodizing treatment conditions A, B, and C were designated as main anodizing treatment layers A, B, and C, respectively.

<Evaluation of Micropores>

The thus obtained structures were evaluated for average pore diameter and average pore interval of their micropores by image analysis of the surface photographs taken with an SEM.

Distance between adjacent pore centers was measured at 30 points in the SEM photograph (gradient, 0 degrees) taken with the FE-SEM adjusted to a magnification of 100,000 times depending on the pore diameter, and the average found was regarded as the average pore interval.

Contours of about 100 pores were traced on a transparent OHP sheet, and approximation to an equivalent circle diameter was performed by using an image analysis package (Image Factory (product name) manufactured by Asahi HiTech Co., Ltd.) so as to regard the found value as the average pore diameter.

As for the traced contours of abount 100 pores, actual areas inside them were also measured, and pore density (/dm²) was calculated by the following equation:
Pore density=100/total actual area

TABLE 19

| Conditions for | | | |
|---|---|---|---|
| main anodizing | | | |
| treatment | A | B | C |
| Electrolyte | Sulfuric acid | Oxalic acid | Phosphoric |
| solution | | | acid |
| Concentration | 0.3 M | 0.5 M | 0.2 M |
| Temperature | 16° C. | 16° C. | 2° C. |
| Voltage | 25 V | 40 V | 195 V |
| Current density | 0.8 A/dm² | 0.4 A/dm² | 0.4 A/dm² |
| Treatment time | 2 minutes | 4 minutes | 4 minutes |
| Layer thickness | 200 nm | 200 nm | 200 nm |
| Average pore | 20 nm | 33 nm | 160 nm |
| diameter | | | |
| Average pore | 63 nm | 100 nm | 500 nm |
| interval | | | |

<Pore Widening Treatment>

The anodized layer was dissolved under the following conditions to carry out uniform sealing treatment by electrolysis.

TABLE 20

| Treatment solution | Temperature | Time |
|---|---|---|
| 50 g/L phosphoric acid | 30° C. | 15 minutes |

<Conditions for Filling of the Metal into the Micropores>
1) Filling of Au

Electrodeposition was conducted by immersing the sample in an Au electrodeposition solution.

More specifically, the electrodeposition was conduced in an aqueous solution of 1g/l HAuCl₄.4H₂O and 7 g/l H₂SO₄ at 30° C. by applying an AC voltage (adjusted with a slidax) of 11 V at 60 Hz for 10 seconds and using a Pt counter electrode.

2) Filling of Co

Electrodeposition was conducted by immersing the sample in a Cu electrodeposition solution.

More specifically, the electrodeposition was conduced in an electrolyte solution containing 5% CoSO₄.7H₂O and 2% H₃BO₃ at room temperature by applying an AC voltage of 5 V.

<Evaluation of Magnetism>

Stylus for the AFM was replaced with the one for magnetic force microscope (MFM), and the magnetism of the sample having Co electrodeposited thereto was measured by using a magnetization measuring system so set as to operate in the direction perpendicular to the sample. Measurement was carried out under the same conditions as those described above after applying the magnetic field to the sample until saturation. The results are shown in Table 21. The MFM is a microscope which uses a cantilever (stylus) coated with a magnetic material for monitoring magnetic properties (state of the magnetic domain, etc.) of the sample surface as the displacement of the cantilever and imaging the properties under non-contact mode measuring conditions.

Contrast is produced in the image being formed depending on whether the cantilever is attracted (image made darker) or repelled (made brighter) by the part where the magnetic material has been filled. Use of such principle has enabled to map the location of the magnetic material. In the relevant Examples, the part of the sample filled with the magnetic material attracted the cantilever, and was indicated by a darker region in the image.

Criteria for Evaluating the Magnetism:

Excellent: An area comprising 80% or more of the total pore area became dark.

Good; An area comprising 50% or more but less than 80% of the total pore area became dark.

Fair: An area comprising 10% or more but less than 40% of the total pore area became dark.

Poor: An area comprising less than 10% of the total pore area became dark.

TABLE 21

| | | Main | | |
|---|---|---|---|---|
| | | anodizing | Metal filled | Evaluation |
| | | treatment | into the | of magnetism |
| | Substrate | layer | micropores | (MFM) |
| Example 13 | 7 | B | Co | Good |
| Example 14 | 7 | C | Co | Excellent |
| Example 15 | 10 | B | Co | Good |
| Example 16 | 10 | C | Co | Excellent |
| Comparative | 22 | B | Co | Poor |
| Example 3 | | | | |
| Comparative | 22 | C | Co | Poor |
| Example 4 | | | | |

<Optical Evaluation>

An adequate amount of rhodamine 6G was dropped onto the sample having Au electrodeposited thereto, and Raman scattering intensity was measured by a Raman spectrometer. The results are shown in Table 22.

Criteria for the Optical Evaluation:

Good: Raman signal was enhanced.

Fair: Raman signal was enhanced but only up to 1/10.

Poor: Raman signal was not detected.

TABLE 22

| | | Main | | |
|---|---|---|---|---|
| | | anodizing | Metal filled | |
| | | treatment | into the | Optical |
| | Substrate | layer | micropores | evaluation |
| Example 17 | 7 | A | Au | Good |
| Example 18 | 10 | A | Au | Good |
| Comparative | 22 | A | Au | Fair |
| Example 5 | | | | |

### Example 19

### Mold Transfer Method

A positive-type electron beam resist (ZEP-520 (product name) manufactured by Zeon Corporation) was applied on a 3.5-inch silicon substrate to a thickness of 0.1 μm by using a spin coater. The substrate was cut into sections having a size of 1 cm×1 cm with a glass cutter.

In an electron beam exposure system, the section was exposed to an electron beam with a diameter of about 30 nm at a regular interval so that the resulting projections will be arranged at an orthogonal lattice (square) with an interval of 100 nm (exposure area, 5 mm×5 mm). The sample was then developed to form micropores in the resist.

Subsequently, chromium was deposited on the sample to a thickness of 50 nm by using an electron beam evaporator. The sample was then immersed in diglyme (a solvent) and sonicated to remove the chromium on the resist together with the resist itself and leave chromium projections each having a diameter of about 100 nm and a height of 50 nm.

The silicon substrate was then subjected to reactive dry etching with CF₄ gas by using these chromium projections as a mask so that it would be etched to a depth of 60 nm. The chromium was then removed with oxygen plasma to leave projections having a diameter of about 30 nm and a height of 60 nm which were arranged in orthogonal lattice at an interval of 100 nm. These silicon projections were pressed against the surface of substrate 4 having been produced as described before at a pressure of 3 tons/cm².

The substrate was then anodized under the main anodizing treatment conditions B to produce a structure having the anodized layer whose micropores were arranged at an orthogonal lattice at an average pore interval of 100 nm.

### Example 20

### Electron Releasing Device

The projections of the silicon mold were pressed against the substrate 4 having a size of 1 cm×5 cm at a pressure of 3 tons/cm². The substrate was then anodized under the main anodizing treatment conditions B to produce a structure having the anodized layer whose micropores were arranged at an orthogonal lattice at an average pore interval of 100 nm. In order to cause the micropores to extend through the barrier layer, a DC voltage of 0.1 V was applied to the structure in 5% phosphoric acid solution at 30° C. and the structure was kept immersed until the current value reached 1 mA/dm² or higher, which took about 15 minutes. The structure was further plated by applying an AC voltage of 5 V for 1 second in an electrolyte solution containing 5% CoSO₄.7H₂O and 2% H₃BO₃ at room temperature to electrolytically deposit metal Co at the bottom of the barrier layer. After reducing with hydrogen, the structure was immersed in cyanuric acid so that the Co will act as a catalyst. The structure was placed in a reaction vessel which was a quartz tube (having a diameter of 50 mm and a length of 100 mm) having water cooling jackets connected to its upstream and downstream ends, respectively. A gas inlet tube was connected to the end of the upstream cooling jacket opposite with that connected to the quartz tube, and a gas outlet tube to the end of the downstream cooling jacket opposite with that connected to the quartz tube. The reaction tube was heated to a temperature of 380 to 420° C., and benzene/nitrogen mixture was allowed to flow through the quartz tube to promote the reaction.

When the structure was observed under SEM, the structure had carbon nanotubes developing from the Co catalyst.

This structure and an anode having a pohsphor were placed in a vacuum chamber so that they oppose with each other at an interval of 1 mm. When a voltage of 1 kV was applied, the phosphor started to emit light, and electron releasing current could be confirmed.

### Example 21

### Photonic Device

The projections of the silicon mold were pressed against the substrate 4 having a size of 1 cm×5 cm at a pressure of 3 tons/cm². The substrate was then anodized under the main anodizing treatment conditions B for 90 minutes to produce a structure having the anodized layer whose micropores were arranged at an orthogonal lattice at an average pore interval of 100 nm. The anodized layer had a thickness of 4 μm. The sample was then immersed in a solution of 5% phosphoric acid at 30° C. for 5 minutes to dissolve the interior of the micropores to thereby facilitate entrance of the resin monomer.

The micropores were filled with a methacrylate monomer in order to fill the micropores with dielectric PMMA. The monomer was polymerized at 60° C. so as to fill the interior of the micropores with PMMA.

This structure was cut into sections of 1 cm×1 cm, and a slice having a thickness of about 100 μm was produced with a microtome. This slice was attached to a PET base, and evaluated on a VIS-IR absorptiometer by transmission method. A strong absorption was observed at a wavelength 500 to 600 nm, which was absent in the sample produced with no pressing of the mold. This revealed that the sample had the property of a photonic crystal.

### Example 22

### Light Emitting Device

The projections of the silicon mold were pressed against the substrate 4 having a size of 1 cm×5 cm at a pressure of 3 tons/cm². The substrate was then anodized under the main anodizing treatment conditions B to produce a structure having the anodized layer whose micropores were arranged at an orthogonal lattice at an average pore interval of 100 nm. In order to cause the micropores to extend through the barrier layer, a DC voltage of 0.1 V was applied to the structure in 5% phosphoric acid solution at 30° C. and the structure was kept immersed until the current value reached 1 mA/dm² or higher, which took about 15 minutes.

The structure was further plated by applying an AC voltage of 5 V for 1 second in an electrolyte solution containing 5% CoSO₄.7H₂O and 2% H₃BO₃ at room temperature to electrolytically deposit metal Co at the bottom of the barrier layer.

The structure was further immersed in an electrolyte solution composed of 0.1 M aqueous solution of zinc nitrate maintained at 60° C. along with a Pt counter electrode, and a voltage of −0.8 V was applied to an Ag/AgCl reference electrode to thereby deposit ZnO in the nanoholes.

When the structure was observed under SEM, deposition of ZnO in the micropores was found. When the structure was irradiated with He—Cd laser beam at a wavelength of 325 nm, a strong light emission was observed at a wavelength of approximately 400 nm, which was not observed for the substrate having ZnO deposited on Co under similar conditions, This indicated that the structure acts as a light emitting device.

What is claimed is:

1. A method for producing a structure comprising:
a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to produce a structure composed of the anodized layer with a plurality of recesses.

2. A method for producing a structure comprising:
a stripping step in which an aluminum member comprising an aluminum substrate and an anodized layer present on the aluminum substrate, which layer contains micropores having an average pore diameter of 10 to 500 nm and a coefficient of variation in pore diameter of less than 30%, is electrolyzed in an aqueous acid solution by using the aluminum member for a cathode to thereby strip the anodized layer off the aluminum substrate so as to obtain the aluminum substrate with a plurality of recesses; and
an anodizing step in which the aluminum substrate with a plurality of recesses is anodized to produce a structure composed of the aluminum substrate with a plurality of recesses that is provided on its surface with an anodized layer containing micropores.

3. The method for producing a structure according to claim 1 wherein the micropores in the structure composed of the anodized layer with a plurality of recesses produced by the stripping step have an average pore diameter of 8 to 200 nm and an average pore interval of 23 to 600 nm.

4. The method for producing a structure according to claim 2 wherein the micropores in the structure produced by the anodizing step have an average pore diameter of 8 to 200 nm and an average pore interval of 23 to 600 nm.

5. The method for producing a structure according to claim 1 wherein the aluminum substrate constituting the aluminum member is the one producible by performing polishing on an aluminum substrate having an aluminum purity of at least 99.9% at least by mechanical polishing to an arithmetical mean roughness Rₐ of up to 0.1 μm and a glossiness of at least 60%.

6. The method for producing a structure according to claim 2 wherein the aluminum substrate constituting the aluminum member is the one producible by performing polishing on an aluminum substrate having an aluminum purity of at least 99.9% at least by mechanical polishing to an arithmetical mean roughness Rₐ of up to 0.1 μm and a glossiness of at least 60%.

7. The method for producing a structure according to claim 5 wherein the mechanical polishing is electrolytic-abrasive polishing.

8. The method for producing a structure according to claim 6 wherein the mechanical polishing is electrolytic-abrasive polishing.

9. A structure obtainable by the method for producing a structure according to claim 1.

10. A structure obtainable by the method for producing a structure according to claim 2.

11. An electromagnetic device comprising the structure obtainable by the method for producing a structure according to claim 1 wherein the plurality of recesses in the structure have in their interior a metal material or a magnetic material.

12. An electromagnetic device comprising the structure obtainable by the method for producing a structure according to claim 2 wherein the micropores in the structure have in their interior a metal material or a magnetic material.

13. A method for producing a nanostructure comprising the steps of performing polishing on an aluminum substrate having an aluminum purity of at least 99.9% at least by mechanical polishing to an arithmetical mean roughness Rₐ of up to 0.1 μm and a glossiness of at least 60%, and further performing anodizing on the aluminum substrate to thereby produce a nanostructure provided in its surface with micropores.

14. The method for producing a nanostructure according to claim 13 wherein the mechanical polishing is electrolytic-abrasive polishing.

15. The method for producing a nanostructure according to claim 13 wherein the micropores have an average pore diameter of 8 to 200 nm and an average pore interval of 23 to 600 nm and preferably 24 to 500 nm.

16. A electromagnetic device comprising the nanostructure obtainable by the method for producing a nanostructure according to claim 13 wherein the micropores having a regular nanostructure in the nanostructure have in their interior a metal material or magnetic material.

17. A nanostructure provided in its surface with micropores which is obtainable by performing anodizing on an aluminum substrate having an aluminum purity of at least 99.9%, an arithmetical mean roughness Rₐ of up to 0.1 μm as calculated from roughness values found in an area of not less than 1 mm² in a rolling direction and a direction perpendicular thereto, and a glossiness of at least 60%.
